(19) United States
(12) Patent Application Publication
(10) Pub. No.: US 2023/0067664 A1
(43) Pub. Date: Mar. 2, 2023

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Chao-Wei Li, Hsinchu City (TW); Tzu-Ting Chou, Hsinchu City (TW); Chun-Yen Lan, Hsinchu County (TW); Yu-Wei Lin, New Taipei City (TW); Sheng-Hsiang Chiu, Tainan City (TW); Chih-Wei Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 17/865,399

(22) Filed: Jul. 15, 2022

Related U.S. Application Data
(63) Continuation-in-part of application No. 17/462,005, filed on Aug. 31, 2021.

(51) Int. Cl. H01L 23/31; H01L 25/16; H01L 25/065; H01L 21/56; H01L 23/367

(52) U.S. Cl. CPC H01L 23/315; H01L 25/165; H01L 25/162; H01L 25/0652; H01L 21/565; H01L 21/563; H01L 23/3675; H01L 24/16

(57) ABSTRACT

A package structure includes a circuit substrate, a package element and a molding layer. The package element is disposed on the circuit substrate and is electrically connected with the circuit substrate. The molding layer is disposed over the circuit substrate and covers at least a top surface of the circuit substrate. The molding layer includes a first portion wrapping around sidewalls of the package element and having a first thickness, and a second portion surrounding the first portion and connected with the first portion. The first thickness of the first portion is larger than a second thickness of the second portion. A top surface of the first portion of the molding layer is higher than a top surface of the package element.

### CROSS-REFERENCE TO RELATED APPLICATION

This application is a continuation-in-part application of and claims the priority benefit of a prior application Ser. No. 17/462,005, filed on Aug. 31, 2021. The entirety of the above-mentioned patent application is hereby incorporated by reference herein and made a part of this specification.

### BACKGROUND

Semiconductor devices and integrated circuits used in a variety of electronic apparatus, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1G are schematic cross-sectional views and top views schematically illustrating various stages of a process for fabricating a package structure in accordance with some embodiments of the present disclosure.

FIG. 2A illustrates a schematic cross-sectional view of a package structure in accordance with some embodiments of the present disclosure.

FIG. 2B is a schematic top view of the package structure illustrated in FIG. 2A.

FIG. 3A through FIG. 3D are schematic cross-sectional views and top views schematically illustrate various stages of a process for fabricating a package structure in accordance with some embodiments of the present disclosure.

FIG. 4A illustrates a schematic cross-sectional view of a package structure in accordance with some embodiments of the present disclosure.

FIG. 4B is a schematic top view of the package structure illustrated in FIG. 4A.

FIG. 4C is a top view of a package structure in accordance with some embodiments of the present disclosure.

FIG. 5 illustrates a schematic cross-sectional view of a package structure in accordance with some embodiments of the present disclosure.

FIG. 6 illustrates a schematic cross-sectional view of a package structure in accordance with some embodiments of the present disclosure.

FIG. 7 illustrates schematic cross-sectional views of various package structures in accordance with some embodiments of the present disclosure.

FIG. 8 illustrates schematic cross-sectional views of various package structures in accordance with some embodiments of the present disclosure.

FIG. 9 illustrates a cross-sectional view of a package structure in accordance with some embodiments of the present disclosure.

FIG. 10 and FIG. 11 schematically illustrate a cross sectional view and a top view of an example of a package structure in accordance with some embodiments of the present disclosure.

FIG. 12 through FIG. 14 illustrate cross sectional views of examples of package structures in accordance with some embodiments of the present disclosure.

FIG. 15 and FIG. 16 illustrate cross sectional views of examples of package structures in accordance with some embodiments of the present disclosure.

FIG. 17 and FIG. 18 illustrate cross sectional views of examples of package structures in accordance with some embodiments of the present disclosure.

FIG. 19 illustrates a cross sectional view of an example of a package structure in accordance with some embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

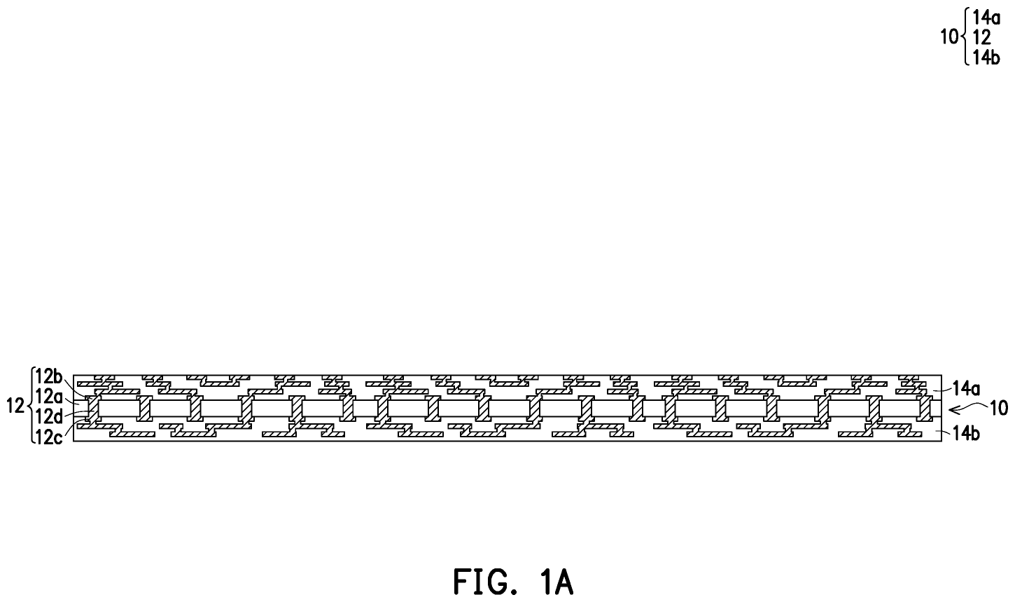

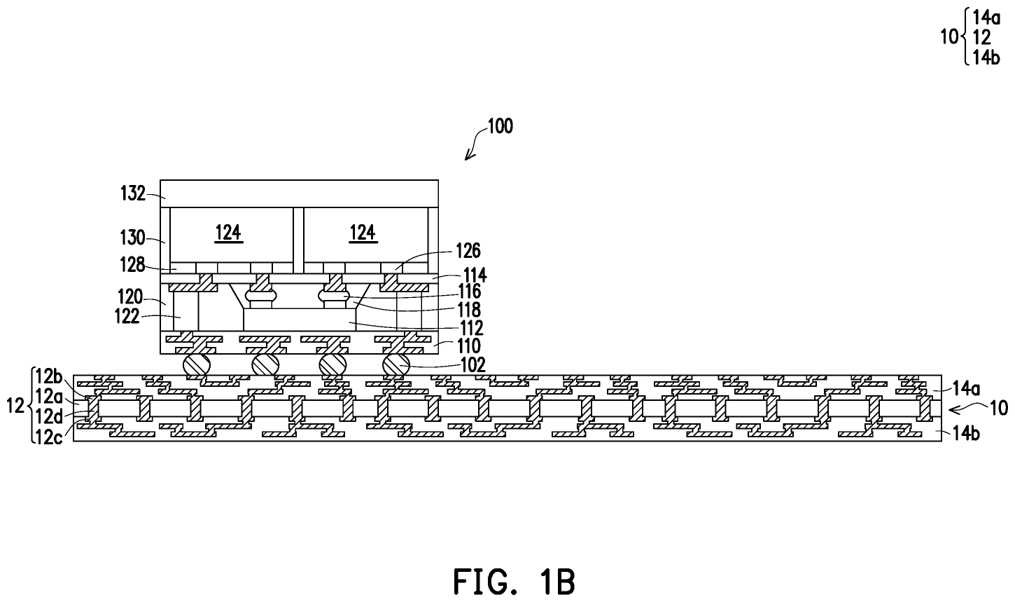

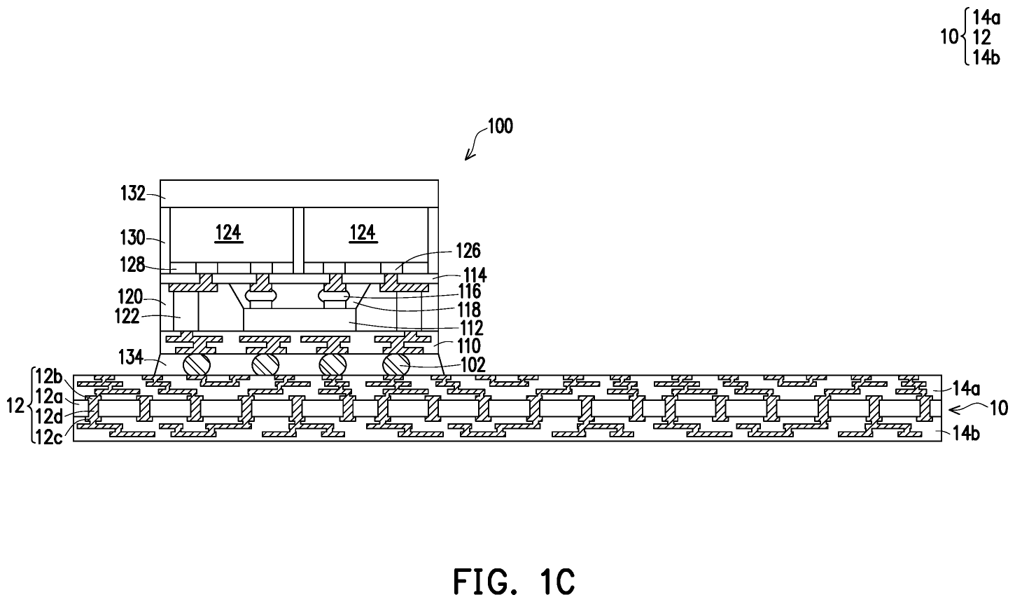

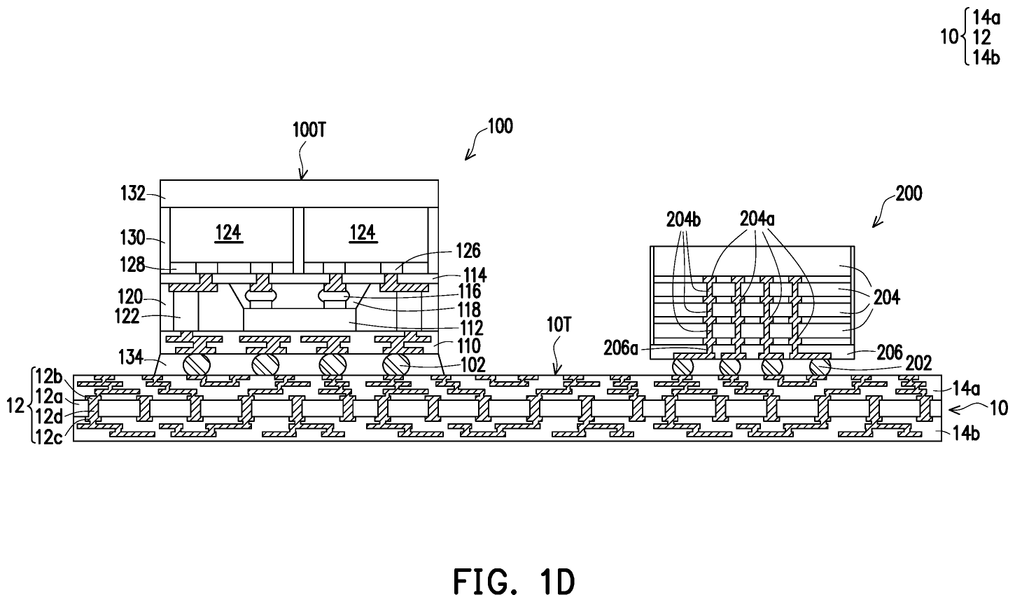

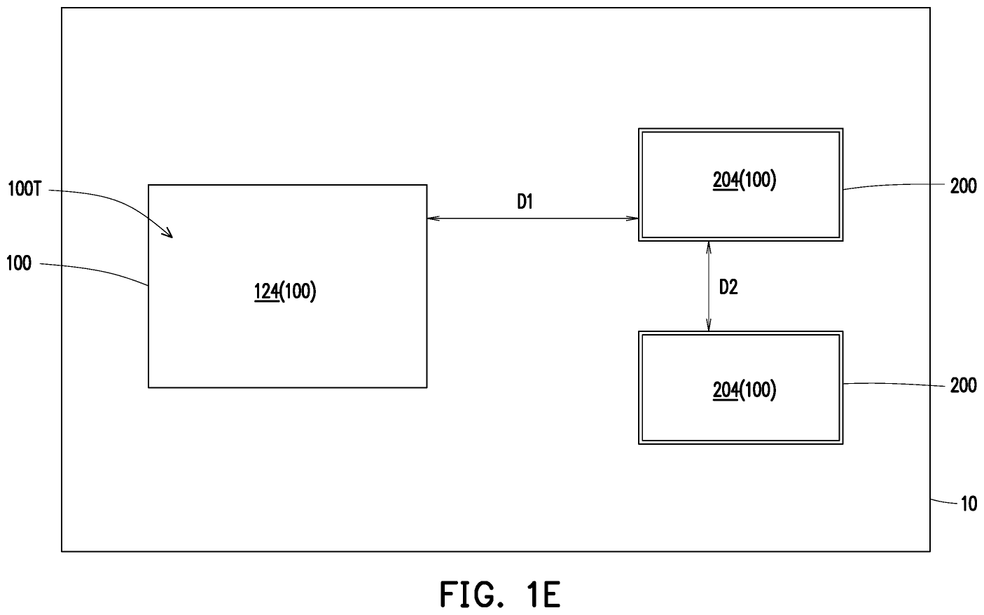

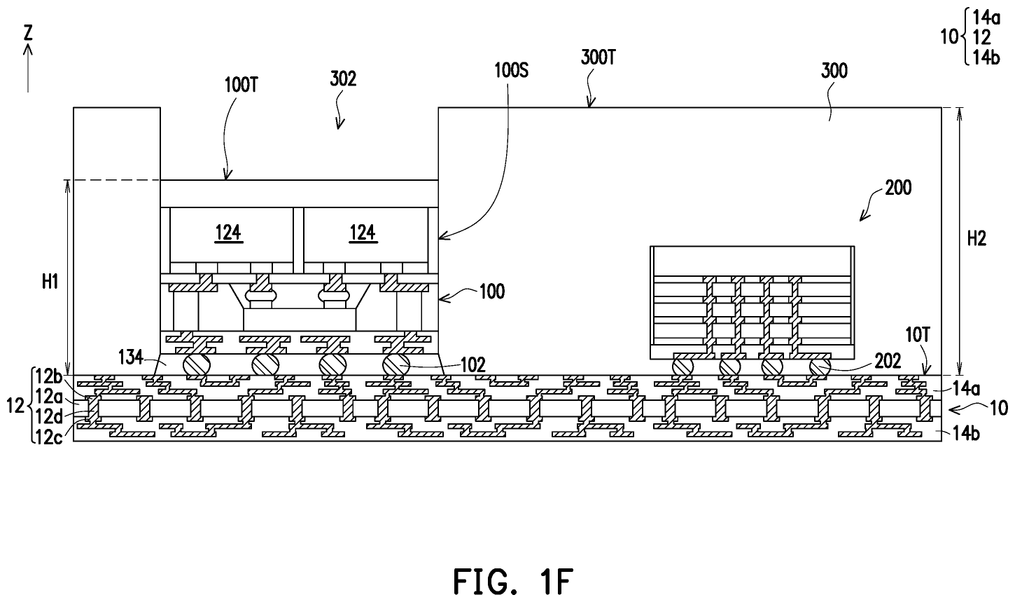

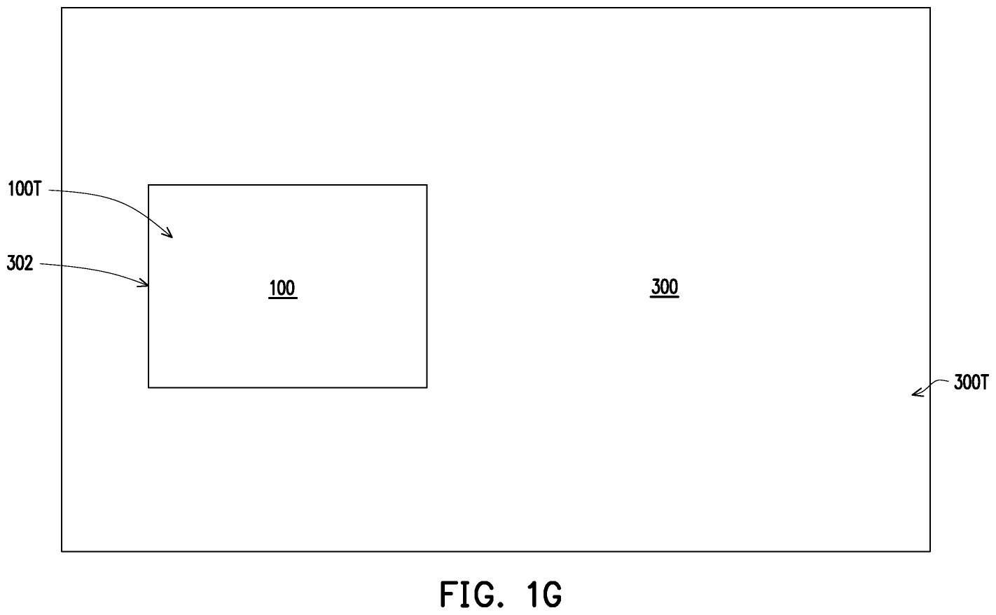

FIG. 1A through FIG. 1G are cross-sectional views and top views schematically illustrating various stages of a process for fabricating a package structure in accordance with some embodiments of the present disclosure.

Referring to FIG. 1A, a substrate 10 is provided. In some embodiments, the substrate 10 includes a circuit substrate, a multilayered board substrate or an organic substrate. In some embodiments, the substrate 10 is a multilayered circuit board substrate or a system board circuit substrate. In some embodiments, the substrate 10 includes a core layer 12, a first build-up layer 14a disposed on a top surface of the core layer 12 and a second build-up layer 14b disposed on a bottom surface of the core layer 12. In some embodiments, the core layer 12 includes a core dielectric layer 12a, a first core conductive layer 12b disposed on an upper surface of the core dielectric layer 12a, a second core conductive layer 12c disposed on a lower surface of the core dielectric layer 12a and plated through holes 12d embedded in and penetrate through the core dielectric layer 12a.

In some embodiments, the core dielectric layer 12a includes prepreg, polyimide, photo image dielectric (PID), Ajinomoto buildup film (ABF), a combination thereof, or the like. However, the disclosure is not limited thereto, and other dielectric materials may also be used.

In some embodiments, the first core conductive layer 12b and the second core conductive layer 12c include copper, gold, tungsten, aluminum, silver, gold, a combination thereof, or the like. In some embodiments, the first core conductive layer 12b and the second core conductive layer 12c are copper foils coated or plated on the opposite sides of the core dielectric layer 12a. In some embodiments, the plated through holes 12d provide electrical paths between the electrical circuits located on the opposite sides of the core layer 12. In some embodiments, the plated through holes 12d are filled with one or more conductive materials. In some embodiments, the plated through holes 12d are lined with a conductive material and filled up with an insulating material. For example, the through holes are plated with copper with an electroplating or an electroless plating.

In some embodiments, the first build-up layer 14a and the second build-up layer 14b are disposed on the opposite sides of the core layer 12. Specifically, the first build-up layer 14a is formed over the first core conductive layer 12b of the core layer 12, and the second build-up layer 14b is formed over the second core conductive layer 12c of the core layer 12. In some embodiments, the formation of the first build-up layer 14a or the second build-up layer 14b includes sequentially forming a plurality of dielectric layers (not shown) and a plurality of conductive patterns (not shown) alternately stacked over the first surface of the core layer 12. In some embodiments, the formation of the first build-up layer 14a or the second build-up layer 14b involves photolithography and/or etching processes. In some embodiments, the formation of the first build-up layer 14a or the second build-up layer 14b involves film lamination followed by a laser drilling process. It is understood that the total number of layers of the first build-up layer 14a and the second build-up layer 14b may be modified based on the product requirements. In some embodiments, the materials of the dielectric layers include polyimide, polybenzoxazole (PBO), benzocyclobutene (BCB), prepreg, Ajinomoto buildup film (ABF), silicon nitride, silicon oxide, a combination thereof, or the like. In some embodiments, the materials of the conductive patterns include a metal material, such as aluminum, titanium, copper, nickel, tungsten, alloys thereof and/or combinations thereof. In some embodiments, the conductive patterns are formed by deposition, or plating.

In some embodiments, the number of layers in the first build-up layer 14a is equal to the number of layers in the second build-up layer 14b. In some embodiments, the first build-up layer 14a and the second build-up layer 14b are electrically connected through the plated through holes 12d.

In some other embodiments, the substrate 10 includes a semiconductor substrate made of an elemental semiconductor such as silicon, diamond or germanium, a compound semiconductor such as gallium arsenide, silicon carbide, indium arsenide, or indium phosphide or an alloy semiconductor, such as silicon germanium carbide, gallium arsenic phosphide, or gallium indium phosphide. In some embodiments, the substrate 10 includes a semiconductor-on-insulator (SOI) substrate such as silicon-on-insulator, germanium-on-insulator (GOI), silicon germanium on insulator (SGOI), or a combination thereof.

Referring to FIG. 1B, a first semiconductor element 100 is mounted on the substrate 10 and bonded to the substrate 10 through a plurality of first connectors 102. In some embodiments, the first semiconductor element 100 is mounted onto the substrate 10 and then a reflow process is performed so that the first semiconductor element 100 is bonded to the bond pad terminals of the substrate 10 through the first connectors 102. In some embodiments, the first connectors 102 include micro bumps, metal pillars, controlled collapse chip connection (C4) bumps, electroless nickel-electroless palladium-immersion gold technique (ENEPIG) formed bumps, a combination thereof (e.g., a metal pillar having a solder thereon), or the like. In some embodiments, the connectors 102 include C4 bumps or micro bumps. In some embodiments, the first connectors 102 include a metallic material such as solder, copper, aluminum, gold, nickel, silver, palladium, tin, a solder material, or combinations thereof. In some embodiments, the first connectors 102 include solder bumps or solder balls. In some embodiments, the solder material includes, for example, lead-based solders such as PbSn compositions, or lead-free solders including InSb compositions, SnCu compositions or SnAg compositions. In some embodiments, the first connectors 102 are formed by using electro or electroless plating techniques, screen-printing or jet printing techniques.

In some embodiments, the first semiconductor element 100 includes or is a package including a multi-chip stacked package, a chip on wafer (CoW) package, an integrated fan-out (InFO) package, a chip-on-wafer-on-substrate (CoWoS) package, a three-dimensional integrated circuit (3DIC) package, or a combination thereof. In some embodiments, the first semiconductor element 100 includes an InFO package. In some embodiments, the first semiconductor element 100 includes a semiconductor die having active elements or functional elements and passive elements. In some embodiments, the first semiconductor element 100 includes one or more semiconductor dies performing different functions, and the semiconductor dies may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die or an application processor (AP) die, or may independently be or include a memory die such as a high bandwidth memory (HBM) die. In some embodiments, the first semiconductor element 100 includes at least one of AP dies, LSI dies or SoC dies.

In some embodiments, the first semiconductor element 100 includes an InFO package, and the first semiconductor element 100 includes a redistribution circuit structure 110, an integrated circuit (IC) 112 disposed on the redistribution circuit structure 110, a redistribution layer 114 disposed on the integrated circuit 112, bumps 116 disposed between the integrated circuit 112 and the redistribution layer 114, and an underfill 118 filled between the integrated circuit 112 and the redistribution layer 114. In some embodiments, the first semiconductor element 100 includes an insulating encapsulation 120 encapsulating the integrated circuit 112, conductive pillars 122 penetrating through the insulating encapsulation 120, integrated circuits 124 disposed on the redistribution layer 114, bumps 126 disposed between the integrated circuits 124 and the redistribution layer 114, an underfill 128 filled between each of the integrated circuits 124 and the redistribution layer 114, and an insulating encapsulation 130 encapsulating the integrated circuits 124. In some embodiments, the first semiconductor element 100 includes an optional protective cover 132 disposed on and covering the integrated circuits 124 and the insulating encapsulation 130.

In some embodiments, the redistribution circuit structure 110 includes alternately stacked dielectric layers and conductive patterns. In some embodiments, the materials of the dielectric layers include polyimide, PBO, BCB, a combination thereof, or the like. In some embodiments, the conductive patterns include metal, such as aluminum, titanium, copper, nickel, tungsten, and/or alloys thereof. In some embodiments, the redistribution layer 114 includes alternatively stacked dielectric layers and conductive patterns, and the materials and formation methods of the redistribution layer 114 may be similar to those of the redistribution circuit structure 110, so that the details are not repeated herein.

In some embodiments, the integrated circuit 112 includes or is an LSI die, and the integrated circuits 124 include or are SoC dies. The integrate circuit 112 is electrically connected with the integrated circuits 124 through the redistribution layer 114, the conductive pillars 122 and the redistribution circuit structure 110. In some embodiments, the bumps 116 include micro bumps, and the bumps 126 include micro bumps. In some embodiments, the insulating encapsulation 120 or 130 includes a molding compound formed by a molding process. In some embodiments, the material of the insulating encapsulation 120 or 130 includes epoxy resin, phenolic resins and/or fillers. The conductive pillars 122 electrically connect the redistribution circuit structure 110 and the redistribution layer 114. In some embodiments, the conductive pillars 122 include metal, such as aluminum, titanium, copper, nickel, tungsten, and/or alloys thereof.

In some embodiments, the protective cover 132 may be adhered onto the top surfaces of the integrated circuits 124 and the insulating encapsulation 130 to provide protection for the InFO package. In some embodiments, the protective cover 132 includes a glass cover. In some embodiments, the protective cover 132 includes a dielectric layer, a passivation layer or a polymeric material layer. Since the protective cover 132 is optionally formed, it is possible that the first semiconductor element 100 has no protective cover and the back surfaces of the integrated circuits 124 are exposed without covering and bare in some embodiments of this disclosure.

Referring to FIG. 1C, in some embodiments, an underfill 134 is formed between the first semiconductor element 100 and the substrate 10 and surrounds the first connectors 102. For example, the underfill 134 may be filled into the space between the first connectors and the substrate 10 by a capillary flow process and then cured. In some embodiments, the underfill 134 includes a resin material including an epoxy resin material without or with fillers such as silica fillers or ceramic fillers. In some embodiments, the underfill 134 fully fills between the first connectors 102 and the substrate 10 to strengthen the structural integrity, which helps to counterbalance the potential warpage of the whole structure.

FIG. 1E is a schematic top view of the package structure illustrated in FIG. 1D. Referring to FIG. 1D and FIG. 1E, two second semiconductor elements 200 are mounted and bonded onto the substrate 10 through a plurality of second connectors 202. In some embodiments, the second semiconductor elements 200 are mounted and bonded to the substrate 10 through the flip chip bonding process. In some embodiments, the second connectors 202 includes C4 bumps or micro bumps. In some embodiments, the second semiconductor elements 200 perform different functions from the first semiconductor element 100 and the first and second semiconductor elements are different types of elements. In certain embodiments, the first semiconductor element 100 may include one or more logic dies, and the second semiconductor elements 200 include one or more memory dies.

In some embodiments, either of the second semiconductor elements 200 includes or is a package including a multi-chip stacked package, a chip on wafer (CoW) package, an integrated fan-out (InFO) package, a chip-on-wafer-on-substrate (CoWoS) package, a three-dimensional integrated circuit (3DIC) package, or a combination thereof. In some embodiments, either of the second semiconductor elements 200 includes or is a semiconductor die having active elements or functional elements and passive elements. In some embodiments, either of the second semiconductor elements 200 includes or is a memory die such as a high bandwidth memory (HBM) die, or may include or be a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die or an application processor (AP) die. In some embodiments, the second semiconductor elements 200 includes memory dies, and the memory dies are HBM die including a plurality of stacked memory chips 204 and a controller 206. Each of the memory chips 204 includes a plurality of micro-bumps 204a, and parts of the memory chips 204 include a plurality of through vias 204b (e.g. through silicon vias). The controller 206 includes a plurality of through vias 206a (e.g. through silicon vias) electrically connected to the second connectors 202. Through the micro-bumps 204a, the through vias 204b and the through vias 206a, the stacked memory chips 204 and the controller 206 are electrically connected. Herein, the second semiconductor elements 200 are bonded to the substrate 10 without filling the underfill.

Although the first semiconductor element 100 is mounted on the substrate 10 before mounting the second semiconductor element 200 as described in some embodiments shown from FIG. 1B to FIG. 1E, it is understood that the mounting sequence of the first and second semiconductor elements is not limited by the embodiments provided herein but can be arbitrarily changed or adjusted.

Referring to FIG. 1E, the first semiconductor element 100 and the second semiconductor element 200 are arranged side by side and separate from one another with proper distances. It is understood that the arrangement of these elements is not limited by the drawings shown herein and may be modified based on the product design. In one embodiment, from a top view, one first semiconductor element 100 and two second semiconductor elements 200 are arranged aside one another, the first semiconductor element 100 located at the left side is spaced apart from the two second semiconductor elements 200 with a distance D1, while the second semiconductor elements 200 located at the right side of the substrate 10 are spaced apart from each other with a distance D2. In some embodiments, the first semiconductor element 100 and the second semiconductor elements 200 are arranged at locations in an unsymmetrical way.

FIG. 1G is a schematic top view of the package structure illustrated in FIG. 1F. Referring to FIG. 1F and FIG. 1G, a molding layer 300 is formed over the substrate 10 with at least an opening 302, and the molding layer 300 covers the top surface 10T of the substrate 10 and the second semiconductor elements 200 but exposes the first semiconductor element 100. In some embodiments, the molding layer 300 encapsulates the second semiconductor elements 200 and at least covers the sidewalls 100S of the first semiconductor element 100. In some embodiments, the molding layer 300 encapsulates the second semiconductor elements 200 and the second connectors 202, so that the molding layer 300 is in direct contact with the second connectors 202. In some embodiments, the molding layer 300 wraps around the sidewalls 100S of the first semiconductor element 100 and the underfill 134.

In some embodiments, the molding layer 300 is formed by molding such as injection molding, transfer molding, compression molding or over-molding. In one embodiment, the formation of the molding layer 300 involves forming a molding material (not shown) over the substrate 10 entirely covering the first semiconductor element 100 and the second semiconductor element 200 by an injection molding process with the molding material in excess. That is, the molding material covers the top surfaces of the first semiconductor element 100 and the second semiconductor element 200 and is higher (in the thickness direction Z) than the first semiconductor element 100 and the second semiconductor element 200. Later, the opening 302 is formed by removing a portion of the molding material by photolithographic and etching processes. In one embodiment, the molding layer 300 is formed by a transfer molding process with a portion of the mold in direct contact with the backside (i.e. top surface) of the first semiconductor element 100 so that the molding layer 300 is formed with the opening 302 to reveal the top surface of the first semiconductor element 100 after demolding.

In some embodiments, the material of the molding layer 300 includes a resin such as an epoxy resin, a phenolic resin or a thermosetting resin material. In one embodiment, the molding layer 300 is made of a molding material having a suitable thermal expansion coefficient. For example, the molding material has a coefficient of thermal expansion CTE1 measured at a temperature lower than the glass transition temperature (Tg) is about 3 to 50 (ppm/° C.). In one embodiment, CTE1 of the molding material of the molding layer 300 ranges from 10 to 25 (ppm/° C.).

As seen in FIG. 1F, the top surface 100T (the backside) of the first semiconductor element 100 is exposed from the opening 302, and the top surface 300T of the molding layer 300 is higher (in the thickness direction Z) than the top surface 100T of the first semiconductor element 100. In one embodiment, the first semiconductor element 100 has a height H1 measuring from the top surface 10T of the substrate 10 to the top surface 100T of the first semiconductor element 100, while the molding layer 300 has a height H2 measuring from the top surface 10T of the substrate 10 to the top surface 300T. In some embodiments, the height H2 of the molding layer 300 is larger than the height H1 of the first semiconductor element 100. In some embodiments, the height H2 is about 30%-100% larger than the height H1. That is, H2 is about 1.3 times to about 2.0 times of the height H1. In some embodiments, the height H2 is about 40%-80% larger than the height H1. That is, H2 is about 1.4 times to about 1.8 times of the height H1. In some embodiments, the height H2 is about 50%-60% larger than the height H1. That is, H2 is about 1.5 times to about 1.6 times of the height H1. Through forming thicker or higher molding layer 300, the molding layer 300 higher than the first semiconductor element 100 helps to relieve and counterbalance the potential warpage of the whole structure.

As seen in FIG. 1G, in one embodiment, the size (or span) of the opening 302 is substantially the same size (or span) of the first semiconductor element 100, and the entire top surface 100T of the first semiconductor element 100 is fully revealed by the opening 302. In one embodiment, the vertical projection of the opening 302 (on to the top surface 100T along the Z axis) is fully overlapped with the top surface 100T of the first semiconductor element 100. In one embodiment, as the top surface 100T of the first semiconductor element 100 is exposed and bare, the opening 302 functions as an air gap existing between the molding layer 300 and the first semiconductor element 100, which promotes the heat dissipation of the first semiconductor element 100. Although in one embodiment, as seen from the top view of FIG. 1G, the sizes (area) of the opening 302 are substantially the same as the sizes (area) of the first semiconductor element 100, and the top surface 100T of the first semiconductor element 100 is fully exposed the opening 302, it is understood that the number of the opening(s), the dimensions, sizes or shapes of the opening(s) are not limited by the embodiments provided herein.

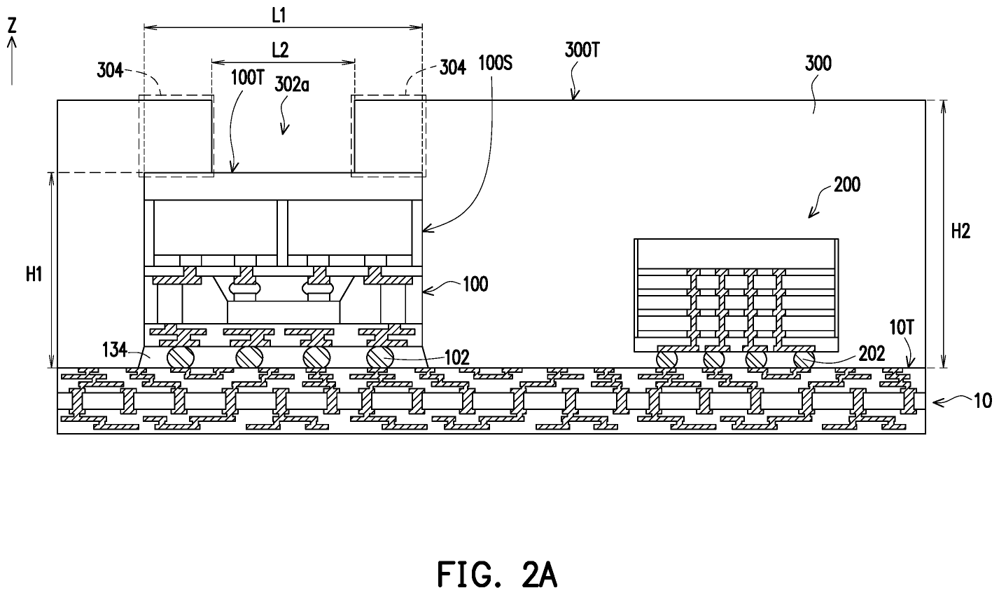

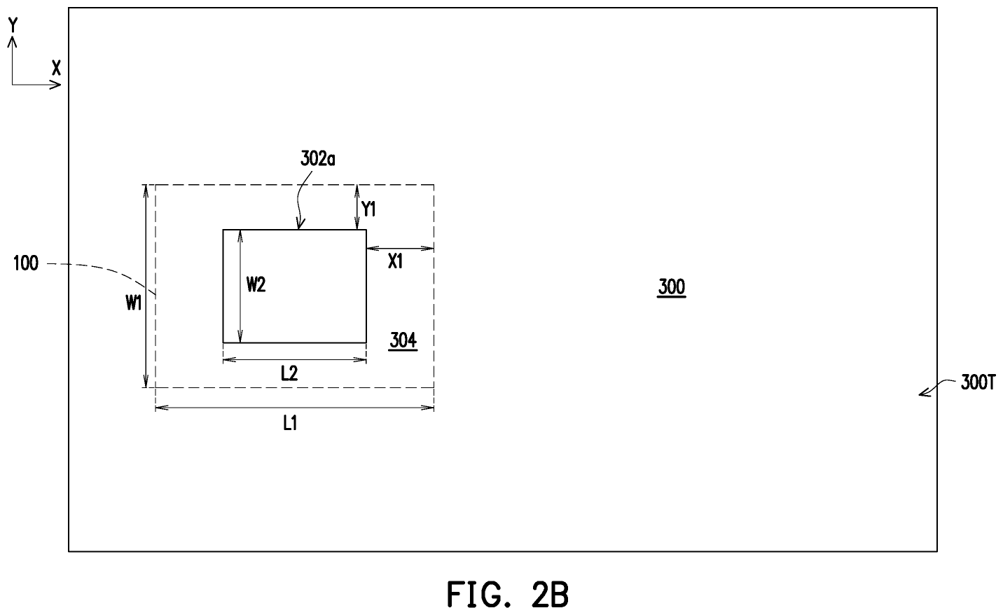

FIG. 2A illustrates a schematic cross-sectional view of a package structure in accordance with some embodiments of the present disclosure. FIG. 2B is a schematic top view of the package structure illustrated in FIG. 2A.

In one embodiment, the package structure illustrated in FIG. 2A and FIG. 2B has a structure similar to the structure illustrated in FIG. 1F and FIG. 1G, except that the molding layer 300 has an opening 302a and the top surface 100T of the first semiconductor element 100 is partially revealed by the opening 302a. As seen in FIG. 2A, the top surface 100T (the backside) of the first semiconductor element 100 is exposed from the opening 302a, and the top surface 300T of the molding layer 300 is higher (in the thickness direction Z) than the top surface 100T of the first semiconductor element 100. Similarly, the height H2 of the molding layer 300 is larger than the height H1 of the first semiconductor element 100. In some embodiments, the height H2 is about 30%-100% larger than the height H1. In some embodiments, the height H2 is about 40%-80% larger than the height H1. In some embodiments, the height H2 is about 50%-60% larger than the height H1.

As seen in FIG. 2B, in one embodiment, the size (or span) of the opening 302a is smaller than the size (or span) of the first semiconductor element 100, and a central portion of top surface 100T of the first semiconductor element 100 is revealed by the opening 302a. In one embodiment, the first semiconductor element 100 (the span of the first semiconductor element 100 is shown as a dashed line rectangle) has a length L1 in the X-direction and a width W1 in the Y-direction, and the opening 302a has a length L2 in the X-direction and a width W2 in the Y-direction. In some embodiments, the length L2 is smaller than the length L1 and is about 5-50% of the length L1, while the width W2 is smaller than the width W1 and is about 5-50% of the width W1. In some embodiments, the length L2 is about 10-40% of the length L1, while the width W2 is about 10-40% of the width W1. In some embodiments, the length L2 is about 20-30% of the length L1, while the width W2 is about 20-30% of the width W1. In some embodiments, the vertical projection of the opening 302a is fully overlapped with the top surface 100T of the first semiconductor element 100, but the area of the vertical projection of the opening 302a is smaller than the whole area of the top surface 100T of the first semiconductor element 100. In some embodiments, the vertical projection of the opening 302a occupies about 25% to about 0.25% of the whole area of the top surface 100T of the first semiconductor element 100. That is, about 25% to about 0.25% (less than 25%) of the whole area of the top surface 100T of the first semiconductor element 100 is revealed by the opening 302a. In some embodiments, about 16% to about 1% of the whole area of the top surface 100T of the first semiconductor element 100 is revealed by the opening 302a. In some embodiments, about 9% to about 4% of the whole area of the top surface 100T of the first semiconductor element 100 is revealed by the opening 302a.

Referring to FIG. 2A and FIG. 2B, in one embodiment, the molding layer 300 has extended portions 304 located directly on the top surface of the first semiconductor element 100, and the extended portions 304 extend from the sidewalls 100S to the opening 302a. The smaller opening 302a is defined by the extended portions 304. From the top view of FIG. 2B, the extension length X1 in the X-direction is about 25-47.5% of the length L1, and the extension length Y1 in the Y-direction is about 25-47.5% of the width W1. In some embodiments, the extension length X1 in the X-direction is about 30-45% of the length L1, and the extension length Y1 in the Y-direction is about 30-45% of the width W1. In some embodiments, the extension length X1 in the X-direction is about 35-40% of the length L1, and the extension length Y1 in the Y-direction is about 35-40% of the width W1. Through forming the molding layer 300 with the extended portions 304, the extended portions 304 in direct contact with the top surface 100T of the first semiconductor element 100 further lessen and counterbalance the potential warpage of the whole structure.

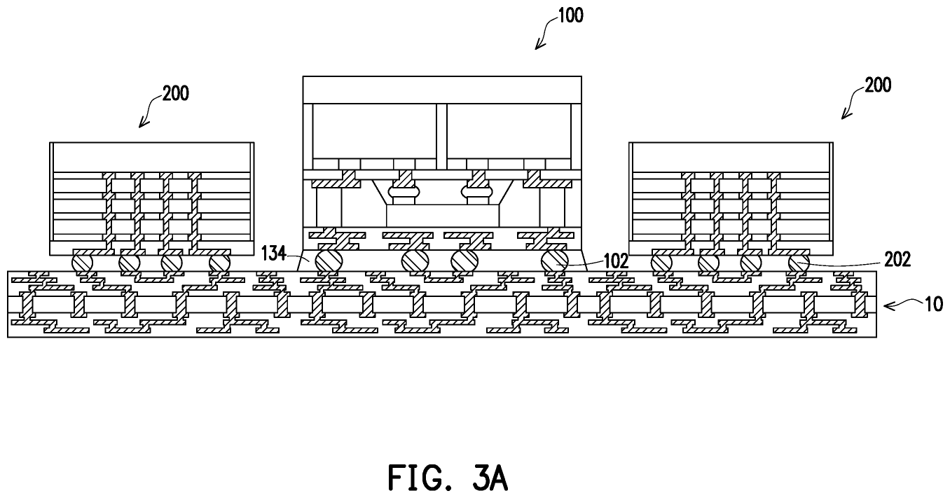

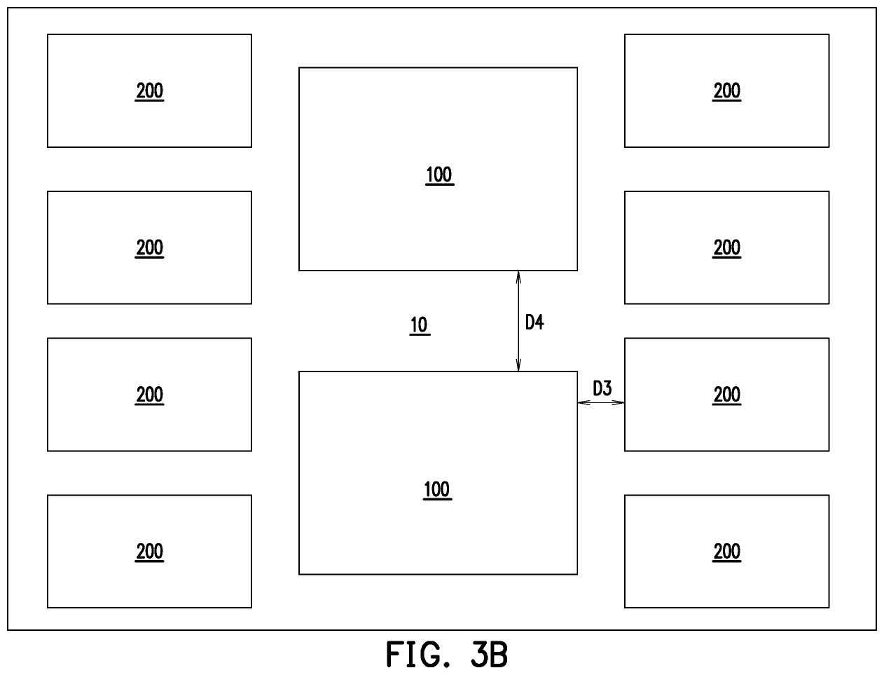

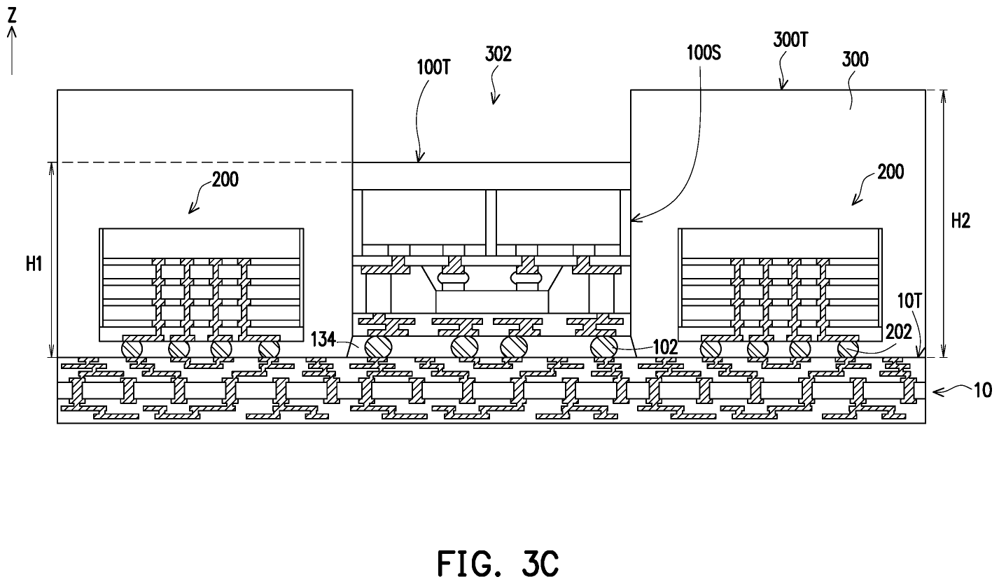

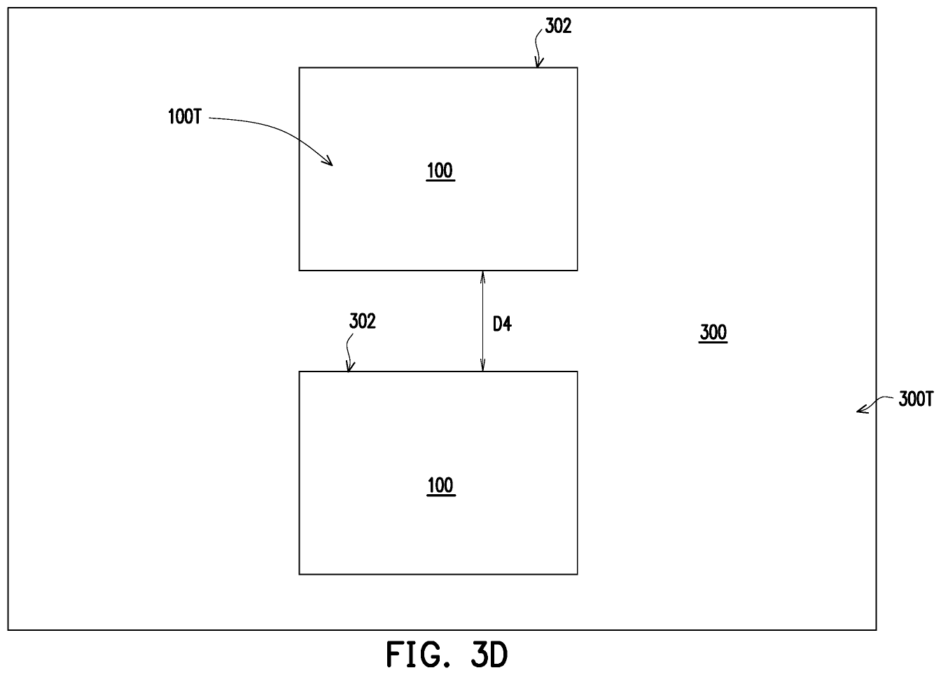

FIG. 3A through FIG. 3D are cross-sectional views and top views schematically illustrate various stages of a process for fabricating a package structure in accordance with some embodiments of the present disclosure. FIG. 3B is a schematic top view of the package structure illustrated in FIG. 3A. FIG. 3D is a schematic top view of the package structure illustrated in FIG. 3C. It is understood that the same or similar reference numbers may be used to label the same or similar elements as described in the previous embodiments, and the details will not be repeated for simplicity.

Referring to FIG. 3A and FIG. 3B, in some embodiments, first semiconductor elements 100 and second semiconductor elements 200 are mounted on and bonded to the substrate 10 respectively through first connectors 102 and second connectors 202 located there-between. In some embodiments, an underfill 134 is filled between the first semiconductor elements 100 and the substrate 10 surrounding the first connectors 102. Herein, the second semiconductor elements 200 are bonded to the substrate 10 without filling the underfill. In some embodiments, the first semiconductor elements 100 are of the same type or perform the same functions, and the second semiconductor elements 200 are of the same type or perform the same functions. In some embodiments, the first semiconductor elements 100 include logic dies, and the second semiconductor elements 200 include memory dies. The forming methods and the materials of the elements the same or similar to those illustrated in the previous embodiments will be omitted.

Referring to FIG. 3B, from the top view, two first semiconductor elements 100 and eight second semiconductor elements 200 mounted on the substrate 10 are arranged side by side, separate from one another with a proper distance. However, the scope of the disclosure is not limited thereto. In one embodiment, the first semiconductor elements 100 and the second semiconductor elements 200 are arranged as three columns, the two first semiconductor elements 100 are arranged in the middle column, two groups of four second semiconductor elements 200 are arranged as two left and right columns beside the middle column. In some embodiments, the four second semiconductor elements 200 in either column are aligned with one another and are spaced apart from the first semiconductor elements 100 with a distance D3, and the two first semiconductor elements 100 are spaced apart from each other with a distance D4. In some embodiments, the first semiconductor elements 100 and the second semiconductor elements 200 are arranged in a symmetrical way.

Referring to FIG. 3C and FIG. 3D, in some embodiments, a molding layer 300 is formed over the substrate 10 with openings 302, and the molding layer 300 covers the top surface 10T of the substrate 10 and the second semiconductor elements 200 but exposes the first semiconductor elements 100. In one embodiment, the two openings 302 are of substantially the same sizes and the locations of the two openings 302 correspond to the locations of the two first semiconductor elements 100. In some embodiments, the molding layer 300 encapsulates the second semiconductor elements 200 and at least covers the sidewalls 100S of the first semiconductor elements 100. In some embodiments, the molding layer 300 encapsulates the second semiconductor elements 200 and the second connectors 202, and the molding layer 300 wraps around the sidewalls 100S of the first semiconductor element 100 and the underfill 134. In some embodiments, the forming methods and the materials of the molding layer 300 are similar to those illustrated in the previous embodiments, and will not be described again.

As seen in FIG. 3C and FIG. 3D, the top surfaces 100T (the backside) of the two first semiconductor elements 100 are exposed from the openings 302, and the top surface 300T of the molding layer 300 is higher (in the thickness direction Z) than the top surface 100T of the first semiconductor element 100. In some embodiments, the height H2 of the molding layer 300 is larger than the height H1 of the first semiconductor element 100. In some embodiments, the height H2 is about 30%-100% larger than the height H1. That is, H2 is about 1.3 times to about 2.0 times of the height H1. In some embodiments, the height H2 is about 40%-80% larger than the height H1. That is, H2 is about 1.4 times to about 1.8 times of the height H1. In some embodiments, the height H2 is about 50%-60% larger than the height H1. That is, H2 is about 1.5 times to about 1.6 times of the height H1. Through forming thicker or higher molding layer 300, the molding layer 300 higher than the first semiconductor element 100 helps to relieve and counterbalance the potential warpage of the whole structure. In FIG. 3D, in one embodiment, the size (or span) of each opening 302 is substantially the same size (or span) of the corresponding first semiconductor element 100, and the entire top surface 100T of the corresponding first semiconductor element 100 is fully revealed by the opening 302. Similarly, the openings 302 may function as air gaps existing between the molding layer 300 and the first semiconductor elements 100, which promote the heat dissipation of the first semiconductor elements 100. It is understood that the number of the opening(s), the dimensions, sizes or shapes of the opening(s) are not limited by the embodiments provided herein.

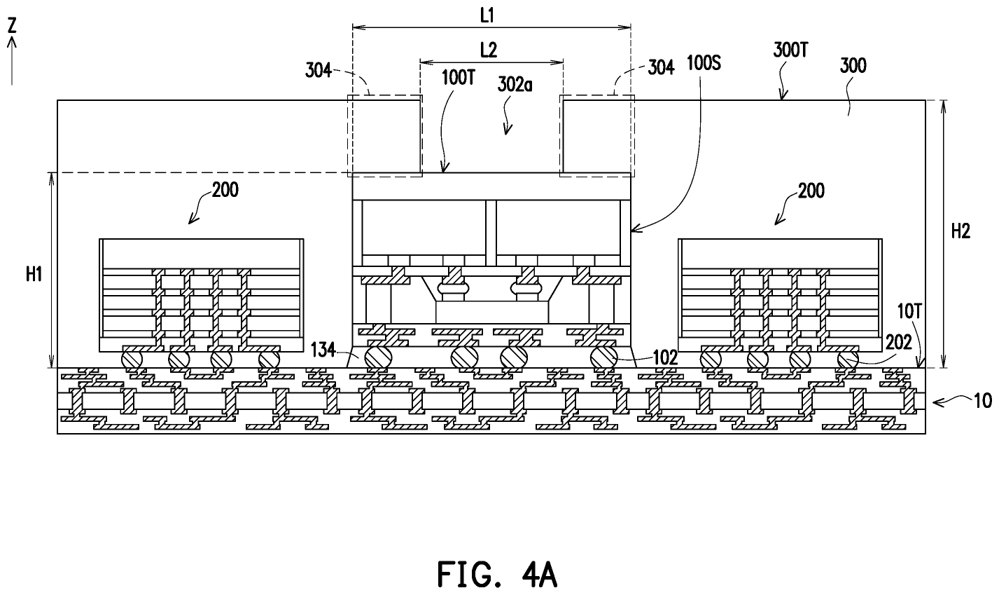

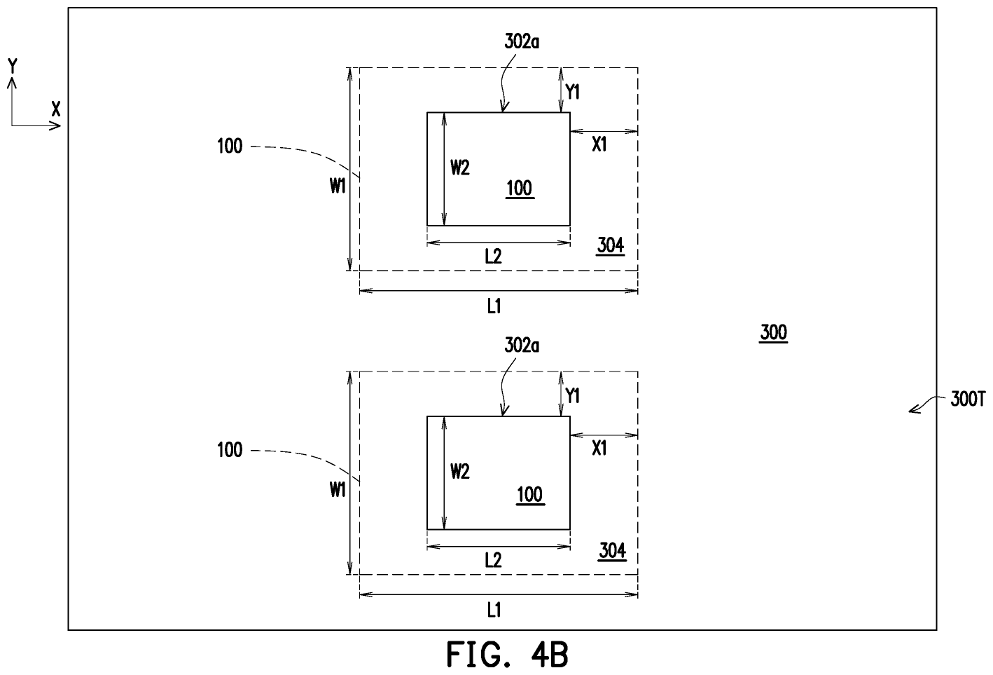

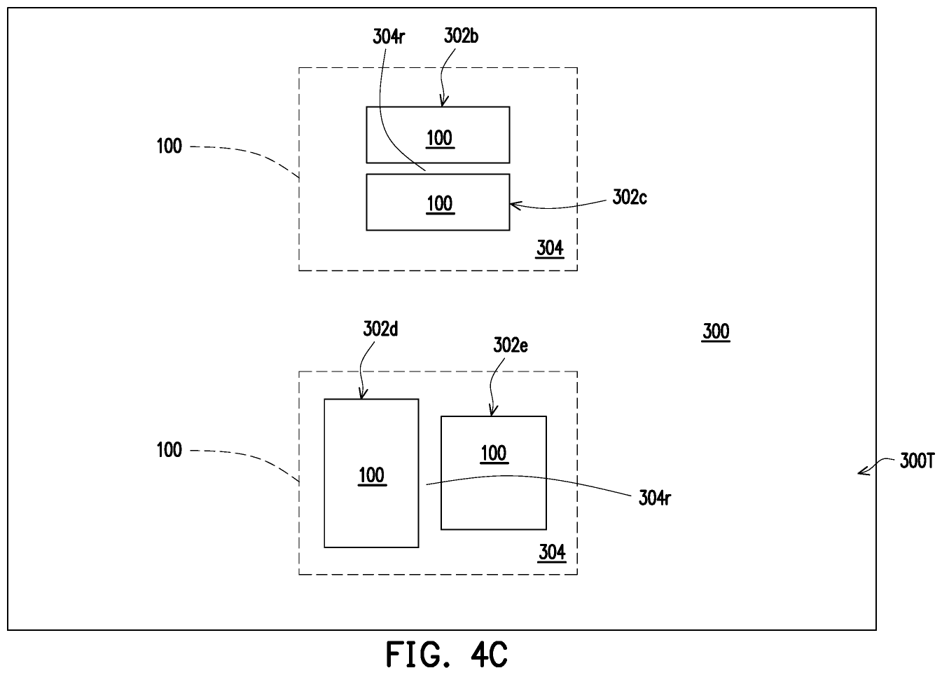

FIG. 4A illustrates a cross sectional view of a package structure in accordance with some embodiments of the present disclosure. FIG. 4B is a top view of the package structure illustrated in FIG. 4A.

In some embodiments, the package structure illustrated in FIG. 4A and FIG. 4B has a structure similar to the structure illustrated in FIG. 3C and FIG. 3D, except that the molding layer 300 has two openings 302a partially revealed the top surfaces 100T of the two first semiconductor elements 100. As seen in FIG. 4A, the top surface 300T of the molding layer 300 is higher than the top surface 100T of the first semiconductor element 100, with the height H2 of the molding layer 300 larger than the height H1 of the first semiconductor element(s) 100. In some embodiments, the height H2 is about 30%-100% larger than the height H1. In some embodiments, the height H2 is about 40%-80% larger than the height H1. In some embodiments, the height H2 is about 50%-60% larger than the height H1. As seen in FIG. 4B, in one embodiment, the two openings 302a are of about the same sizes and the locations of the two openings 302a correspond to the locations of the two first semiconductor elements 100. In some embodiments, the size (or span) of either opening 302a is smaller than the size (or span) of the underlying first semiconductor element 100, and a central portion of the top surface 100T of the first semiconductor element 100 is revealed by the corresponding opening 302a.

In one embodiment, the first semiconductor element 100 (the span of the first semiconductor element 100 is shown as a dashed line rectangle) has a length L1 and a width W1, and the smaller opening 302a has a length L2 and a width W2. In some embodiments, the length L2 is about 5-50% of the length L1, while the width W2 is about 5-50% of the width W1. In some embodiments, the length L2 is about 10-40% of the length L1, while the width W2 is about 10-40% of the width W1. In some embodiments, the length L2 is about 20-30% of the length L1, while the width W2 is about 20-30% of the width W1. In some embodiments, the area of the vertical projection of the opening 302a is smaller than the whole area of the top surface 100T of the first semiconductor element 100. In some embodiments, the vertical projection of the opening 302a occupies about 25% to about 0.25% of the whole area of the top surface 100T of the first semiconductor element 100. That is, about 25% to about 0.25% of the whole area of the top surface 100T of one first semiconductor element 100 is exposed from one openings 302a. In some embodiments, about 16% to about 1% of the whole area of the top surface 100T of the first semiconductor element 100 is revealed by the opening 302a. In some embodiments, about 9% to about 4% of the whole area of the top surface 100T of the first semiconductor element 100 is revealed by the opening 302a.

Referring to FIG. 4A and FIG. 4B, in one embodiment, the molding layer 300 has extended portions 304 located directly on the top surface of the first semiconductor element 100, and the extended portions 304, from the sidewalls 1005, extend inwardly along the top surface 100T with an extension length X1 in the X-direction and an extension length Y1 in the Y-direction. In other words, the smaller opening 302a is defined by the extended portions 304. In some embodiments, the extension length X1 is about 25-47.5% of the length L1, and the extension length Y1 is about 25-47.5% of the width W1. In some embodiments, the extension length X1 in the X-direction is about 30-45% of the length L1, and the extension length Y1 in the Y-direction is about 30-45% of the width W1. In some embodiments, the extension length X1 in the X-direction is about 35-40% of the length L1, and the extension length Y1 in the Y-direction is about 35-40% of the width W1. Through forming the molding layer 300 with the extended portions 304, the extended portions 304 in direct contact with the top surface 100T of the first semiconductor element 100 further lessen and counterbalance the potential warpage of the whole structure.

FIG. 4C is a schematic top view of a package structure in accordance with some embodiments of the present disclosure.

Referring to FIG. 4C, in one alternative embodiment, the molding layer 300 has openings 302b, 302c, 302d and 302e, and the top surface 100T of either first semiconductor element 100 is partially revealed by two separate openings. As seen in FIG. 4C, the two openings 302b and 302c are arranged above the upper first semiconductor element 100, while the two openings 302d and 302e are arranged above the lower first semiconductor element 100. In some embodiments, the two openings 302b, 302c are separate from each other, the two openings 302d, 302e are separate from each other, and the molding layer 300 has a rib portion 304r extending in the X-direction between the two openings 302b and 302c and another rib portion 304r extending in the Y-direction between the two openings 302d and 302e. In some embodiments, for the upper first semiconductor element 100, the vertical projections of the two openings 302b and 302c totally occupy about 90% to about 5% of the whole area of the top surface 100T of the first semiconductor element 100, and the extended portions 304 and the rib portion 304r occupy about 10% to about 95% of the whole area of the top surface 100T of the first semiconductor element 100. In some embodiments, for the upper first semiconductor element 100, the vertical projections of the two openings 302b and 302c totally occupy about 65% to about 45% of the whole area of the top surface 100T of the first semiconductor element 100, and the extended portions 304 and the rib portion 304r occupy about 35% to about 55% of the whole area of the top surface 100T of the first semiconductor element 100. In some embodiments, the vertical projections of the two openings 302d and 302e totally occupy about 90% to about 5% of the whole area of the top surface 100T of the first semiconductor element 100, and the extended portions 304 and the rib portion 304r occupy about 10% to about 95% of the whole area of the top surface 100T of the first semiconductor element 100. In some embodiments, the vertical projections of the two openings 302d and 302e totally occupy about 75% to about 55% of the whole area of the top surface 100T of the first semiconductor element 100, and the extended portions 304 and the rib portion 304r occupy about 25% to about 45% of the whole area of the top surface 100T of the first semiconductor element 100. Although the openings 302b, 302c, 302d, 302e are shown as rectangular openings in FIG. 4C, the arrangements, the number and the shapes of the openings may be adjusted or modified as long as the extended portions and/or the rib portion(s) occupy certain area percentage of the top surface of either first semiconductor element 100. In one embodiment, some of the openings 302b, 302c, 302d, 302e have different shapes.

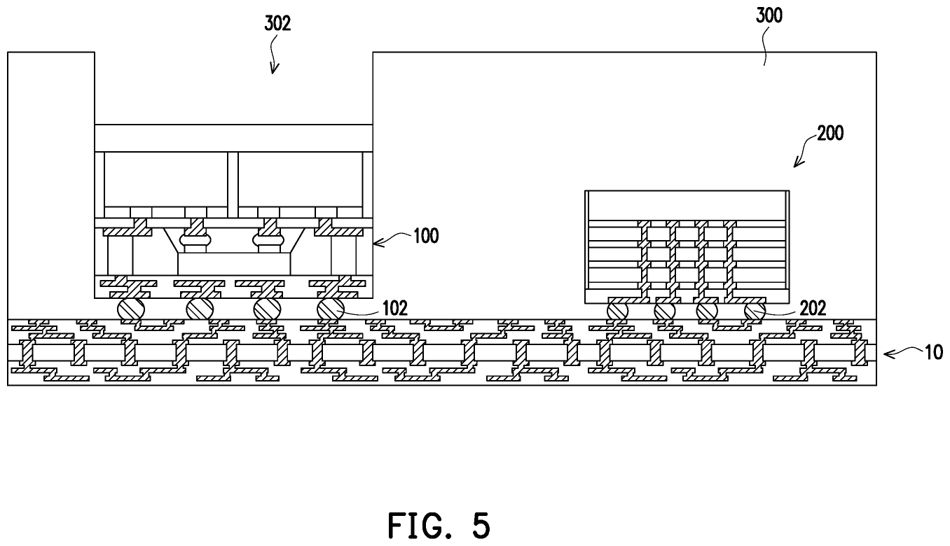

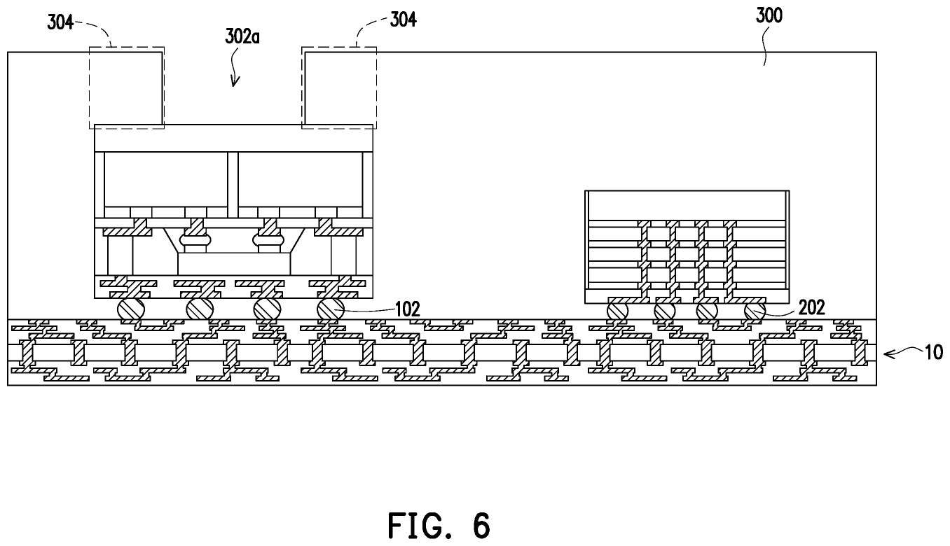

FIG. 5 and FIG. 6 are schematic cross-sectional views of package structures in accordance with some embodiments of the present disclosure. For purpose of clarity and simplicity, detail description of same or similar features may be omitted, and the same or similar reference numbers denote the same or like components. The package structure shown in FIG. 5 is similar to the structure shown in FIG. 1F and may be fabricated following the similar process steps described in the previous embodiments, but no underfill is formed between the first semiconductor element 100 and the substrate 10 to secure the first semiconductor element 100 so that the molding layer 300 is in direct contact with the connectors 102. The package structure shown in FIG. 6 is similar to the structure shown in FIG. 2A and may be fabricated following the similar process steps described in the previous embodiments, but no underfill is formed between the first semiconductor element 100 and the substrate 10 to secure the first semiconductor element 100 so that the molding layer 300 is in direct contact with the connectors 102.

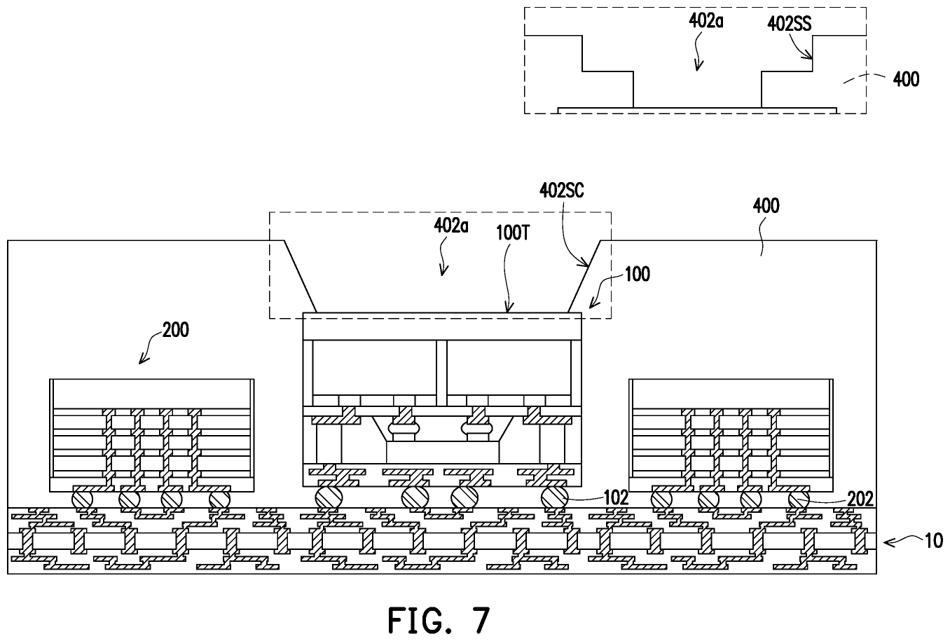

FIG. 7 illustrates schematic cross-sectional views of various package structures in accordance with some embodiments of the present disclosure. The package structure shown in

FIG. 7 is similar to the structure shown in FIG. 4A, except that a molding layer 400 having at least one opening 402a is formed over the substrate 10. In some embodiments, the molding layer 400 is formed by a transfer molding process, and the opening 402a may be formed in various shapes though the design of the mold. In some embodiments, the opening 402a exposes a portion of the top surface 100T of the first semiconductor element 100, the opening 402a has slant sidewalls 402SC, and the opening 402a may have a shape of inverted conical frustum from the top view. In some embodiments, the span of the top of the opening 402a is equivalent to or slightly larger than the span of the underlying first semiconductor element 100, while the span of the bottom of the opening 402a is smaller than the span of the underlying first semiconductor element 100. In some other embodiments, the span of the top of the opening 402a may be larger than the span of the underlying first semiconductor element 100, while the span of the bottom of the opening 402a is equivalent to the span of the underlying first semiconductor element 100. In some embodiments, as seen from the partial cross-sectional view shown at the top right part of FIG. 7, the opening 402a has sidewalls 402SS with staircase side profiles. In some embodiments, for the opening 402a with sidewalls 402SS, the span of the top of the opening 402a may be larger than the span of the underlying first semiconductor element 100, while the span of the middle or the bottom of the opening 402a is smaller than the span of the underlying first semiconductor element 100. In some other embodiments, the span of the top of the opening 402a may be larger than the span of the underlying first semiconductor element 100, while the span of the bottom of the opening 402a is equivalent to the span of the underlying first semiconductor element 100.

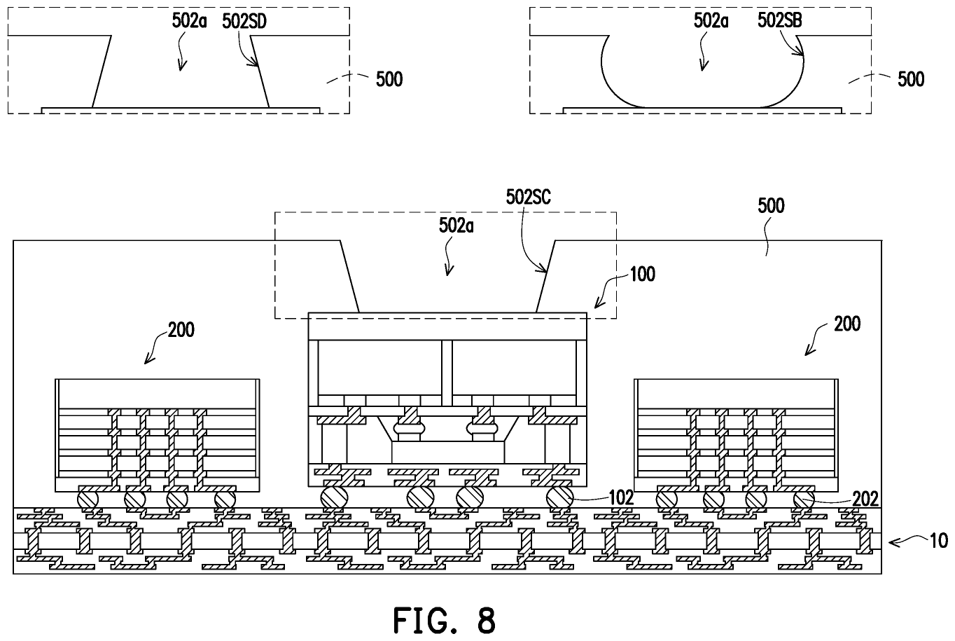

FIG. 8 illustrates schematic cross-sectional views of various package structures in accordance with some embodiments of the present disclosure. The package structure shown in FIG. 8 is similar to the structure shown in FIG. 4A, except that a molding layer 500 having at least one opening 502a is formed over the substrate 10. In some embodiments, the opening 502a exposes a portion of the top surface 100T of the first semiconductor element 100 and the opening 502a has slant sidewalls 502SC, and the opening 502a may have a shape of inverted conical frustum from the top view. In some embodiments, the span of the top or the bottom of the opening 502a is smaller than the span of the underlying first semiconductor element 100.

In some embodiments, the opening 502a may be formed in the molding layer 500 through an etching process, and depending on the etching process used, the opening 502a may be formed with various sidewall profiles. In some embodiments, as seen from the partial cross-sectional view shown at the top left part of FIG. 8, the opening 502a has sloped sidewalls 502SD, and the opening 502a may have a shape of conical frustum from the top view. In some embodiments, as seen from the partial cross-sectional view shown at the top right part of FIG. 8, the opening 502a has curved bowl-shaped sidewalls 502SB.

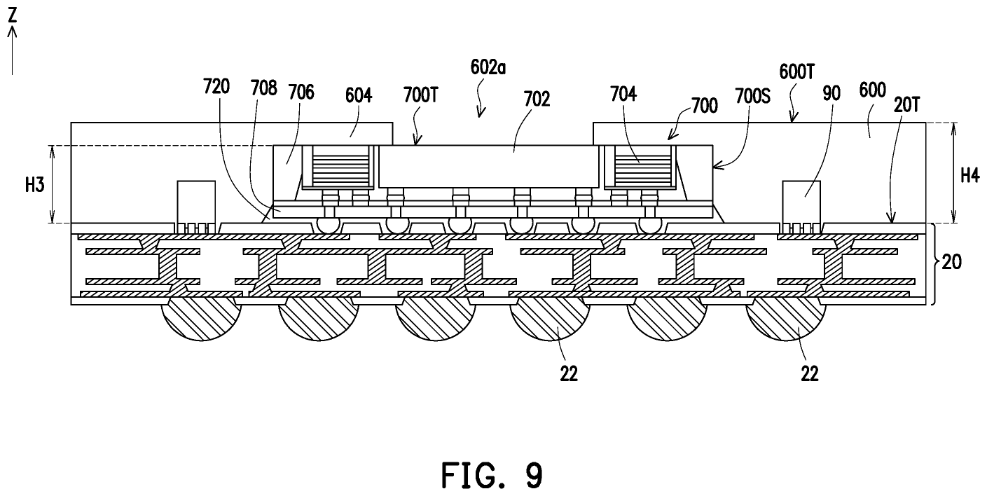

FIG. 9 illustrates a cross sectional view of a package structure in accordance with some embodiments of the present disclosure.

In some embodiments, a package 700 and passive components 90 are bonded to and electrically connected to a substrate 20, and a molding layer 600 having at least one opening 602a is formed over the substrate 20 and covers the package 700 and the passive components 90. In some embodiments, the molding layer 600 covers the top surface 20T of the substrate 20 and the passive components 90 but exposes a top surface 700T of the package 700. In some embodiments, conductive balls 22 are formed on the bottom surface of the substrate 20, and the package 700 and the passive components 90 are electrically connected with the substrate 20 and some of the conductive balls 22. In some embodiments, the molding layer 600 at least covers a portion of the top surface 700T and covers the sidewalls 700S of the package 700. In some embodiments, an underfill 720 is filled between the package 700 and the substrate 20 to secure the bonding between the package 700 and the substrate 20 and further improves the structural integrity of the structure. In some embodiments, the molding layer 600 wraps around the package 700 and the underfill 720. In one embodiment, the package 700 includes or is a chip-on-wafer-on-substrate (CoWoS) package, and the package 700 includes a first die 702 and second dies 704 laterally wrapped by an encapsulant 706 and an interposer 708 for electrically connecting the first and second dies with the underlying substrate 20. In one embodiment, the first die 702 includes a system-on-integrated-circuit (SoIC) die, and the second dies 704 include memory dies.

As seen in FIG. 9, the top surface 700T (the backside) of the package 700 is exposed from the opening 602a, and the top surface 600T of the molding layer 600 is higher (in the thickness direction Z) than the top surface 700T of the package 700. In some embodiments, the height H4 of the molding layer 600 is larger than the height H3 of the package 700. In some embodiments, the height H4 is about 30%-100% larger than the height H3. In some embodiments, the height H4 is about 40%-80% larger than the height H3. In some embodiments, the height H4 is about 50%-60% larger than the height H3. In one embodiment, the size (or span) of the opening 602a is smaller than the size (or span) of the package 700, and a central portion of the top surface 700T of the package 700 is revealed by the opening 602a. That is, the top surface 700T of the package 700 is exposed and bare. In one embodiment, a portion of the backside of the first die 702 is exposed by the opening 602a and the span of the opening 602a may be smaller than the span of the first die 702. In some embodiment, about 25% to about 0.25% of the whole area of the top surface 700T of the package 700 is revealed by the opening 602a. In some embodiments, about 16% to about 1% of the whole area of the top surface 700T of the package 700 is revealed by the opening 602a. In some embodiments, about 9% to about 4% of the whole area of the top surface 700T of the package 700 is revealed by the opening 602a. In one embodiment, as the top surface 700T of the package 700 (e.g. the top surface of the first die 702) is exposed and bare, the opening 602a functions as an air gap, which promotes the heat dissipation of the package 700 (especially the first die 702).

Referring to FIG. 9, in one embodiment, the molding layer 600 has extended portions 604 located directly on the top surface 700T of the package 700, and the extended portions 604 extend from the sidewalls 700S inwardly into the span of the first die 702. Through forming the molding layer 600 with the extended portions 604, the extended portions 604 in direct contact with the top surface 700T of the package 700 lessen and counterbalance the potential warpage of the whole structure.

In some embodiments, due to the molding layer having the thickness larger than some of the elements or packages, the package structures with less warpage and compact in sizes are obtained through straightforward fabricating processes. In some embodiments, the warpage of the package structure may be decreased by 15% to 35% compared to the package structures with leveled molding layer. Furthermore, thermal dissipation of the package structure is also improved as air gaps present above the revealed portions of the elements in the package structure.

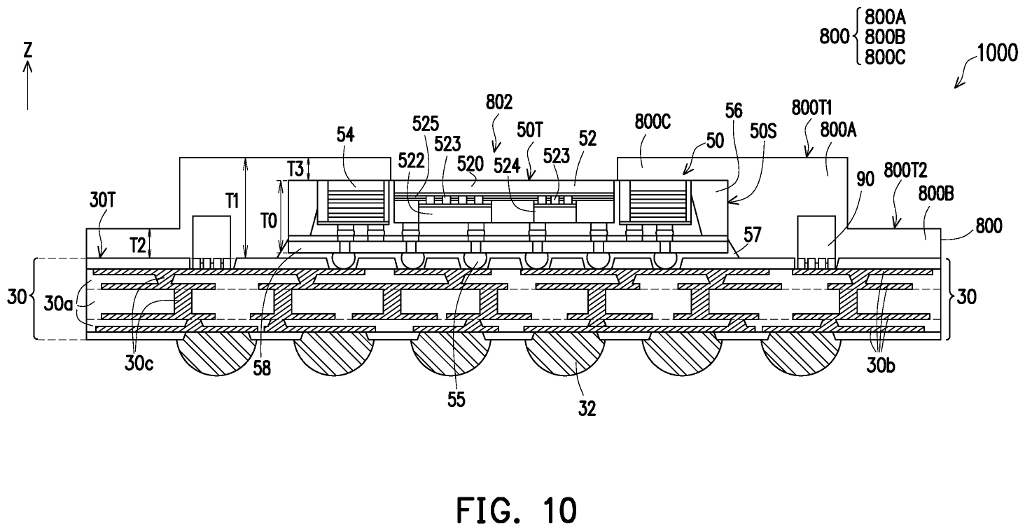

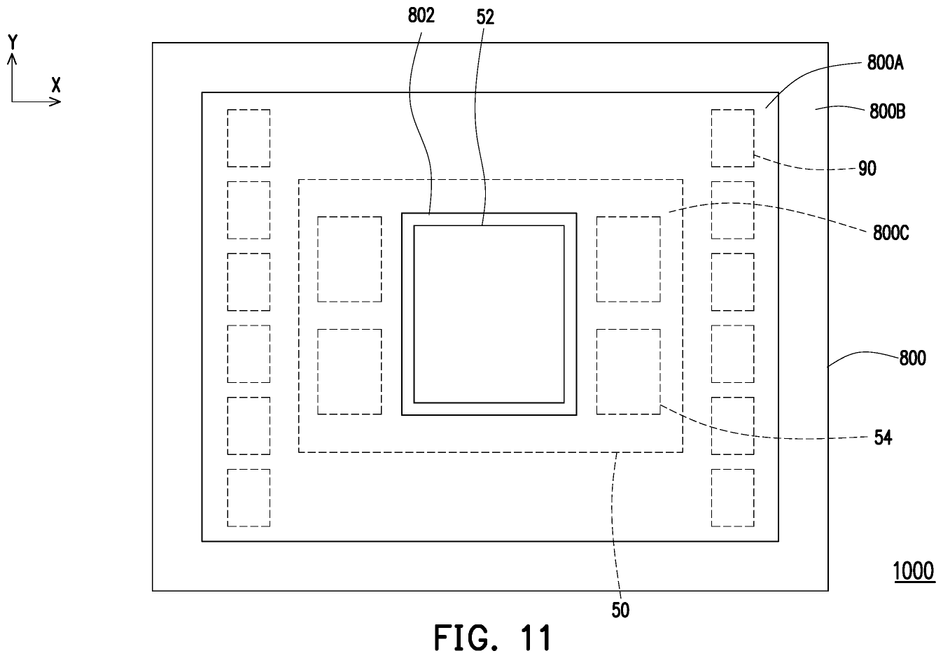

FIG. 10 and FIG. 11 schematically illustrate a cross sectional view and a top view of an example of a package structure in accordance with some embodiments of the present disclosure.

In some embodiments, referring to FIG. 10, the package structure 1000 includes a substrate 30, at least one package 50, and passive components 90. In some embodiments, the substrate 30 is a circuit substrate including a flexible circuit substrate, a multilayered laminated substrate or an organic substrate. In some embodiments, the substrate 30 includes alternatively laminated dielectric layers 30a and metallic layers 30b, and vias 30c interconnecting the metallic layers 30b. In some embodiments, the materials of the dielectric layers 30a include polyimide, polyester, polybenzoxazole (PBO), benzocyclobutene (BCB), silicon nitride, silicon oxide, a combination thereof, or the like. In some embodiments, the materials of the metallic layers 30b and vias 30C include a metallic material, such as aluminum, titanium, copper, nickel, tungsten, alloys thereof and/or combinations thereof. In some embodiments, the passive components 90 include capacitors, inductors, resistors, diodes, transformers or combinations thereof. In some embodiments, the package element or package 50 includes or is a CoWoS package, and the package 50 is bonded to and electrically connected with the substrate 30 through the bumps 55. In some embodiments, the bumps 55 include micro bumps, metal pillars, controlled collapse chip connection (C4) bumps, or combinations thereof. In some embodiments, the package 50 includes a first die 52 and second dies 54 laterally wrapped by an encapsulant 56 and an interposer 58 with through vias for electrically connecting the first and second dies 52, 54 with the underlying substrate 30. For example, the first and second dies 52 and 54 perform different functions. In one embodiment, the first die 52 includes a system-on-integrated-circuit (SoIC) die, and the second dies 54 include memory dies. In one embodiment, the first die 52 includes a first chip 520, a second chip 522 and a third chip 524, the second chip 522 and the third chip 524 are bonded with the first chip 520 through bonding pads 523 and bonding films 525 (i.e. through hybrid bonding technique). In one embodiment, the first and second dies 52 and 54 perform different functions, the first die 52 consumes more power and generates more heat (demanding higher thermal dissipation efficacy) while the second dies 54 generates less heat and is less demanding in that aspect.

In some embodiments, as shown in FIG. 10, the package 50 and the passive components 90 are bonded to and electrically connected to the substrate 30, and a molding layer 800 is formed over the substrate 30 and covers the package 50 and the passive components 90. In some embodiments, the molding layer 800 is formed by molding such as injection molding, transfer molding, compression molding or over-molding. In one embodiment, the molding layer 800 is formed by over-molding to extra molding material, and later the extra molding material is removed through photolithographic and etching processes. In one embodiment, the molding layer 800 is formed by transfer molding with a portion of the mold (not shown) in direct contact with the backside (i.e. top surface) of the element 50 so that the molding layer 800 is formed with the opening 802 to exposed the top surface of the element 50 and formed with the staircase structure after demolding.

In some embodiments, an underfill 57 is filled between the package 50 and the substrate 30 to secure the bonding between the package 50 and the substrate 30, which improves the structural integrity of the structure 1000. In some embodiments, conductive balls 32 are formed on the bottom surface of the substrate 30. In some embodiments, the conductive balls 32 include ball grid array (BGA) balls, solder balls or C4 bumps. In some embodiments, through the substrate 30, the package 50 is electrically connected with some or all of the conductive ball 32 for further electrical connection.

In some embodiments, in FIG. 10 and FIG. 11, the molding layer 800 includes at least one opening 802, and the molding layer 800 covers the top surface 30T of the substrate 30 and the passive components 90 but exposes a portion of the package 50 through the opening 802. Herein, the opening 802 is shown with substantially vertical sidewalls but it is understood that the sidewalls of the opening 802 may be sloped or curved depending on the processes. In some embodiments, the molding layer 800 at least covers the sidewalls 50S of the package 50, and the molding layer 800 has an extended portion 800C that extends from the sidewall 50S into the span of the package 50 covering the second dies 54 of the package 50, so that the first die 52 is exposed through the opening 802. In some embodiments, the exposure of the first die 52 of the package 50 improves the thermal dissipation efficacy and thus enhance the performance and the reliability of the package structure. In some embodiments, the molding layer 800 wraps around the package 50, the passive components 90 and the underfill 57.

In FIG. 10 and FIG. 11, in some embodiments, the molding layer 800 includes the innermost extended portion 800C located above the package 50, a thicker middle portion 800A having a maximum thickness T1 (in Z-axis, measuring from the surface 30T) surrounding the extended portion 800C and the package 50 and a thinner outer portion 800B having a maximum thickness T2 surrounding the middle portion 800A. In some embodiments, the extended portion 800C has a maximum thickness T3, the thickness T3 or T2 is smaller than the thickness T1. In some embodiment, the ratio of T3 to T1 (T3/T1) is about 0.2 to 0.7 and the ratio of T2 to T1 (T2/T1) is about 0.3 to about 0.7. In some embodiments, the package 50 has a thickness T0 smaller than the thickness T1 and larger than the thickness T2. As seen in FIG. 10, in some embodiments, the top surfaces of the extended portion 800C and the middle portion 800A are coplanar with and flush with each other and may be referred to have the same top surface. In some embodiments, the thinner outer portion 800B of the molding layer 800 covers the peripheral and marginal regions of the substrate 30, and the outer portion 800B covers the substrate 30 without encapsulating any active components or passive components or any semiconductor dies there-between. That is, the outer portion 800B may be considered as a device free portion with only the molding material.

As seen in FIG. 11, depending on the arrangement of the dies of the package, the opening 802 is big enough to expose the first die 52 of the package 50, and the extended portion 800C covers the second dies 54 of the package 50, the middle portion 800A covers the passive components 90, and the outer portion 800B extends from the sides of the middle portion 800A to the side edges of the package structure 1000. In some embodiments, the outer portion 800B may be referred as the peripheral portion of the molding layer 800 since the outer portion 800B merely covers the substrate 30 without covering the package, die or passive components.

In some embodiments, the thicker middle portion 800AB as well as the extended portion 800C help to counterbalance or offset the warpage of the package 50, while the thinner outer portion 800B further compensates the warpage of the bordering part of the substrate 30.

In some embodiments, through the staircase structure (i.e. the thicker portion and the outer thinner portion) of the molding layer, the whole package structure is formed with much less or minimum warpage, especially lessening the edge warpage of the substrate. In some embodiments, the warpage of the package structure may be decreased by 20% to 60% compared to the package structures with the molding layer leveled with the enclosed element(s) and having a uniform thickness. Furthermore, thermal dissipation efficacy of the package structure is enhanced as air gap in the opening improves the heat dissipation of the exposed element(s) in the package structure.

From the top view of FIG. 11, it is understood that the extending length(s) of the extended portion 800C in the X-direction may be different from the extending length(s) of the extended portion 800C in the Y-direction, and the opening 802 may be formed in accordance with the size or shape of the first die 52 so as to fully expose the first die 52. In some embodiments, the extending length may be tuned based on the warpage level but less than 45% of the length/width of the underlying package or die.

As seen in FIG. 10, relative to the top surface 30T of the substrate 30, the top surface 800T1 of the extended portion 800C and the middle portion 800A is higher than the top surface 50T of the package 50, and the top surface 800T2 of the outer portion 800B is lower than the top surfaces 800T1 and 50T but higher than the top surface 30T. From FIG. 10, the sidewall(s) connecting the surfaces 800T1 and 800T2 are shown to be substantially vertical sidewall(s), however, it is understood that the sidewall(s) may be sloped or curved sidewall(s).

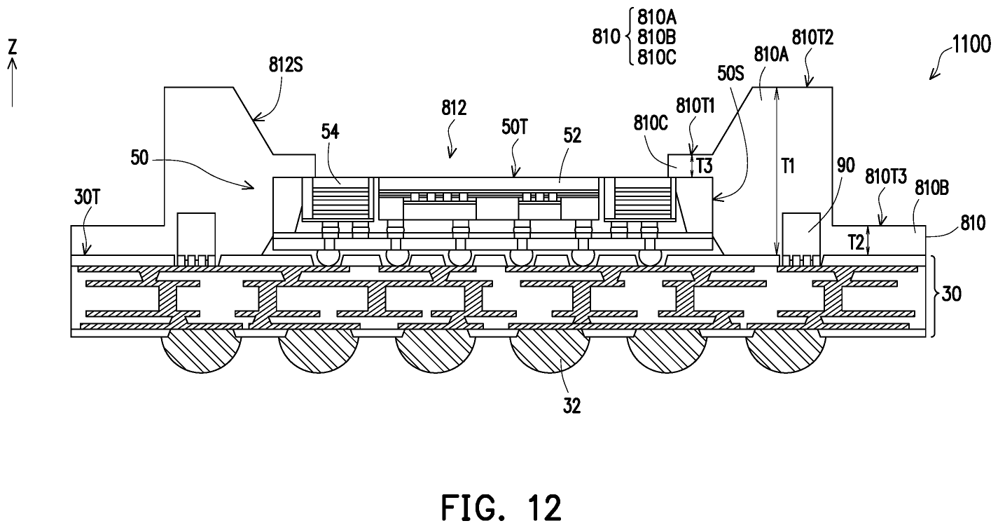

FIG. 12 through FIG. 14 illustrate cross sectional views of examples of package structures in accordance with some embodiments of the present disclosure. Similar structural elements and electronic components may be referred to with the same or similar reference labels, and the detailed descriptions will not be repeated.

Referring to FIG. 12, in some embodiments, the package structure 1100 includes the substrate 30, one or more packages 50 and the passive components 90 mounted on and bonded to the substrate 30 and a molding layer 810 disposed on the substrate 30. In some embodiments, the molding layer 810 includes at least one opening 812, and the molding layer 810 covers the top surface 30T of the substrate 30 and the passive components 90 but exposes a portion of the package 50 through the opening 812. As seen in FIG. 12, the opening 812 has slant sidewalls 812S and exposes the first die 52 and the second dies 54 of the package 50. In some embodiments, the exposure of the first and second dies 52, 54 improves the thermal dissipation efficacy of the package 50 and thus enhance the performance and the reliability of the package structure. In FIG. 12, the molding layer 810 has an extended portion 810C that extends from the sidewall 505 into the span of the package 50 and covers portions of the second dies 54. In FIG. 12, in some embodiments, in addition to the innermost extended portion 800C having the thickness T3 and located above the package 50, the molding layer 810 includes a thicker middle portion 810A having the maximum thickness T1 (in Z-axis, from the surface 3 T) surrounding the extended portion 810C and the package 50 and a thinner outer portion 810B having the thickness T2 surrounding the middle portion 810A. In some embodiments, the thickness T3 or T2 is smaller than the thickness T1. In some embodiment, the ratio of T3 to T1 (T3/T1) is about 0.1 to 0.8 and the ratio of T2 to T1 (T2/T1) is about 0.2 to about 0.7.

As seen in FIG. 12, relative to the top surface 30T of the substrate 30, the top surface 810T1 of the extended portion 810C is lower than the top surface 810T2 of the middle portion 810A but both top surfaces 810T1, 810T2 are higher than the top surface 50T of the package 50, and the top surface 810T3 of the outer portion 810B is lower than the top surfaces 810T1, 810T2 and 50T but higher than the top surface 30T. In some embodiments, as the middle portion 810A becomes thicker (i.e. the top surface 810T2 is higher than the top surface 810T1), the extending length of the extended portion 810C may be adjusted and the opening 812 becomes larger to expose more of the package 50.

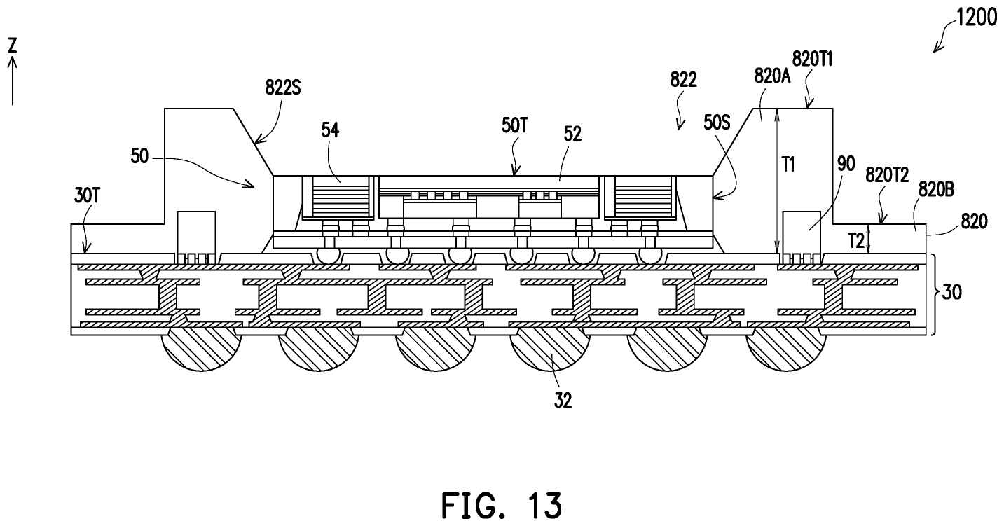

Referring to FIG. 13, in some embodiments, the package structure 1200 includes a molding layer 820 disposed over the substrate 30 and one or more packages 50 and the passive components 90 mounted on and bonded to the substrate 30. In some embodiments, the molding layer 820 includes at least one opening 822, and the molding layer 820 covers the top surface 30T of the substrate 30 and the passive components 90 but exposes the top surface 50T of the package 50 through the opening 822. As seen in FIG. 13, the opening 822 fully exposes the first die 52 and the second dies 54 of the package 50. In FIG. 13, in some embodiments, the opening 822 of the molding layer 820 has slant sidewalls 822S, and the molding layer 820 includes a thicker portion 820A surrounding the package 50 and covering the sidewalls 50S of the package 50 and the passive components 90 and an outer portion 820B around the thicker portion 820A.

Compared with the molding layer 810 in FIG. 12, the molding layer 820 as seen in FIG. 13 has no extended portion. In some embodiments, the thickness T2 of the outer portion 820B is smaller than the thickness T1 of the inner portion 820A. In some embodiment, the ratio of T2 to T1 (T2/T1) is about 0.2 to about 0.7. As seen in FIG. 13, relative to the top surface 30T of the substrate 30, the top surface 820T1 of the portion 820A is higher than the top surface 50T of the package 50, and the top surface 820T2 of the outer portion 820B is lower than the top surfaces 820T1 and 50T but higher than the top surface 30T.

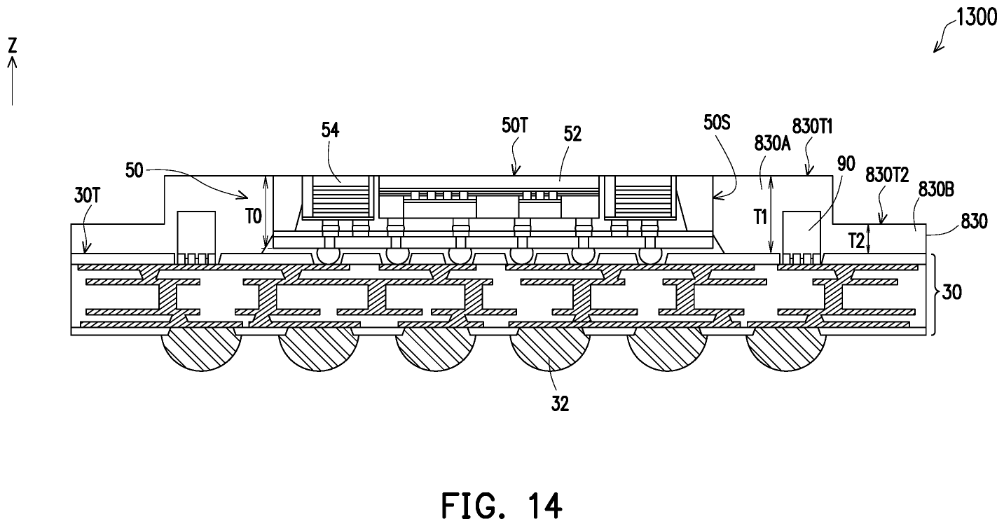

Referring to FIG. 14, in some embodiments, the package structure 1300 includes a molding layer 830 disposed over the substrate 30 and one or more packages 50 and the passive components 90 mounted on and bonded to the substrate 30. In some embodiments, the molding layer 830 covers the top surface 30T of the substrate 30 and the passive components 90 but exposes the top surface 50T of the package 50. As seen in FIG. 14, the molding layer 830 laterally wraps the package 50 (covering the sidewalls 50S) but exposes the first die 52 and the second dies 54 of the package 50. In FIG. 14, in some embodiments, the molding layer 830 includes a thicker portion 830A surrounding the package 50 and covering the sidewalls 50S of the package 50 and the passive components 90 and an outer thinner portion 830B around the thicker portion 830A.

Compared with the molding layer 810 in FIG. 12, the molding layer 830 has no extended portion, and the top surface 830T1 of the thicker portion 830A is coplanar with and flush with the top surface 50T of the package 50. In some embodiments, the thickness T2 of the outer portion 830B is smaller than the thickness T1 of the inner portion 830A. In some embodiment, the ratio of T2 to T1 (T2/T1) is about 0.3 to about 0.8. In some embodiments, the package 50 has a thickness T0 smaller than the thickness T1 and larger than the thickness T2. As seen in FIG. 14, relative to the top surface 30T of the substrate 30, the top surface 830T2 of the outer portion 830B is lower than the top surfaces 830T1 and 50T but higher than the top surface 30T.

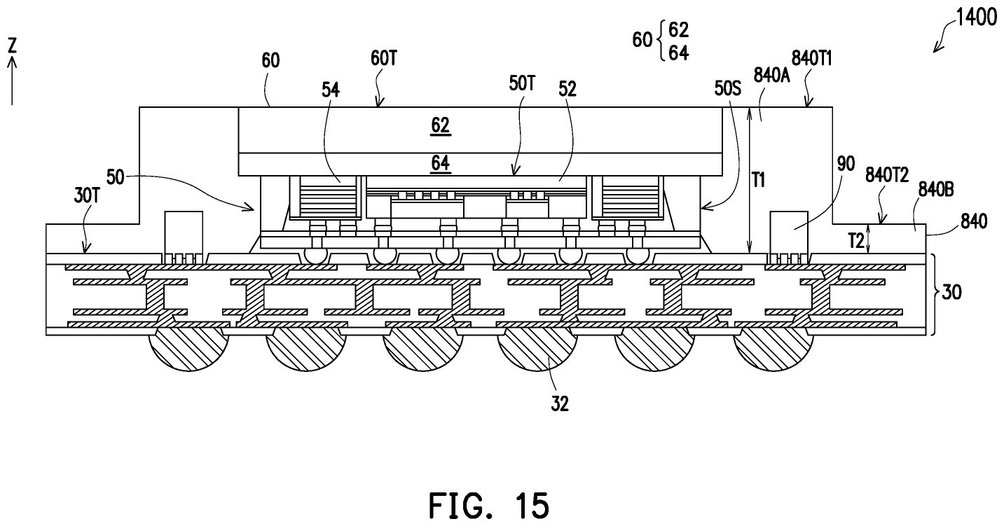

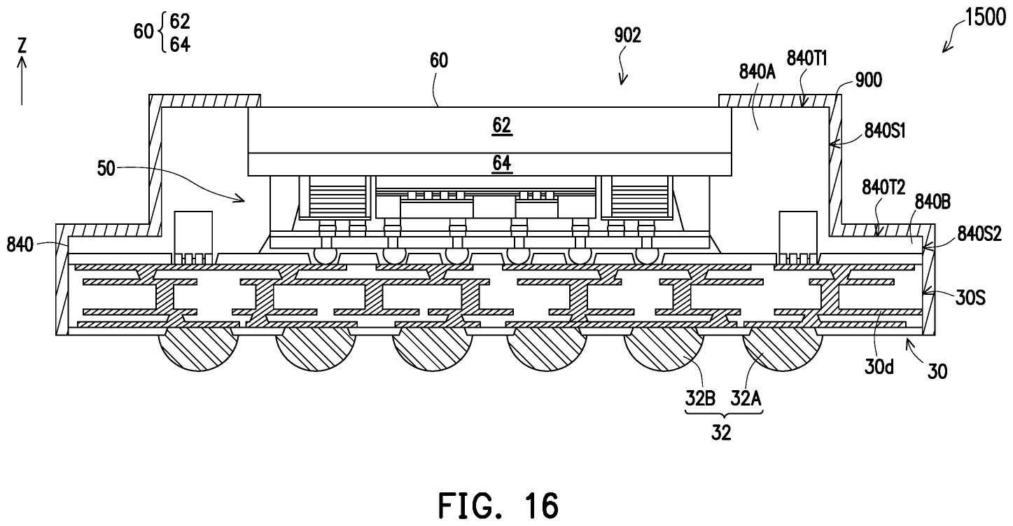

FIG. 15 and FIG. 16 illustrate cross sectional views of examples of package structures in accordance with some embodiments of the present disclosure.

Referring to FIG. 15, in some embodiments, the package structure 1400 includes a molding layer 840 disposed over the substrate 30 and one or more packages 50 and the passive components 90 mounted on and bonded to the substrate 30. In some embodiments, the package structure 1400 further includes a heat dissipating module 60 disposed on the package 50, the heat dissipating module includes a metal lid 62 and a thermal interface material (TIM) 64 disposed between the metal lid 62 and the package 50. In some embodiments, the span of the heat dissipating module 60 is larger than the span of the package 50, and the heat dissipating module 60 covers the package 50 with the TIM 64 in direct contact with the first die 52 and the second dies 54. Through the heat dissipating module 60, the heat dissipation efficacy of the package 50 is further enhanced. Also, the metal lid 62 of the heat dissipating module 60 can help to alleviate the warpage.

In some embodiments, the metal lid 62 is formed from the material of high thermal conductivity, such as steel, stainless steel, copper (Cu), aluminum, gold, nickel, alloys thereof, or combinations thereof. In some other embodiments, the metal lid 62 is a single contiguous plate or includes multiple pieces that may be made of the same or different materials. In some embodiments, the TIM 64 is applied to the metal lid 62 before the attachment of the heat dissipating module 60 onto the package 50. In some embodiments, the material of the TIM 64 includes a material with higher thermal conductivity, such as silver (Ag), Cu, tin (Sn), indium (In), or even carbon nanotube (CNT), graphite, graphene, and a polymeric adhesive material such as silicone or epoxy resins.

In FIG. 15, in some embodiments, the molding layer 840 covers the top surface 30T of the substrate 30 and the passive components 90 but exposes the top surface 60T of the heat dissipating module 60. As seen in FIG. 15, the molding layer 840 encapsulates the package 50 (covering the sidewalls 505) and laterally wraps the heat dissipating module 60. In FIG. 15, in some embodiments, the molding layer 840 includes a thicker portion 840A surrounding the heat dissipating module 60 and the package 50 and covering the sidewalls 60S of the heat dissipating module 60, the sidewalls 505 of the package 50 and the passive components 90, and an outer thinner portion 840B around the thicker portion 840A.

Compared with the molding layer 830 in FIG. 14, the molding layer 840 similarly has no extended portion, and the top surface 840T1 of the thicker portion 840A is coplanar with and flush with the top surface 60T of the heat dissipating module 60. In some embodiments, the thickness T2 of the outer portion 840B is smaller than the thickness T1 of the inner portion 840A. In some embodiment, the ratio of T2 to T1 (T2/T1) is about 0.3 to about 0.8. As seen in FIG. 15, relative to the top surface 30T of the substrate 30, the top surface 840T2 of the outer portion 840B is lower than the top surfaces 840T1 and 60T, lower than the top surface 50T of the package 50 but higher than the top surface 30T.

Referring to FIG. 16, in some embodiments, the package structure 1500, similar to the package structure 1400, further includes a shielding layer 900 covering the molding layer 840 and sidewalls 30S of the substrate 30. In some embodiments, the shielding layer 900 formally covers the portions 840A and 840B and contacts the top surfaces 840T1 and 840T2, the sidewalls 840S1 that connect the surfaces 840T1 and 840T2 and sidewalls 840S2 that connect the surface 840T2 and the bottom surface of the molding layer 840. In some embodiments, the sidewalls 840S2 are aligned with and the sidewalls 30S, and both are covered by the shielding layer 900. As seen in FIG. 16, the shielding layer 900 has an opening 902 exposing the heat dissipating module 60. In some embodiments, the material of the shielding layer includes a material of higher thermal conductivity, such as Ag, Cu, or a conductive material. In some embodiments, the shielding layer 900 contacts the peripheral of the metal lid 62 and contacts the sidewalls 30S of the substrate 30, and the shielding layer 900 is in contact with a ground plate 30d of the substrate 30 and is grounded through the ball(s) 32A of the conductive balls 32.

In some embodiments, the shielding layer 900 functions as the electromagnetic interference (EMI) shielding layer, and the shielding layer 900 together with the metal lid 62 form an EMI shield structure to protect and shield the enclosed dies or packages from electromagnetic interference radiation or signals. In some embodiments, the EMI shielding layer 900 is electrically connected with the ground plate 30d of the substrate 30 and further electrically connected to the grounding ball 32A for grounding. In some embodiments, through the substrate 30, the package 50 is electrically connected with other conductive balls 32B for further electrical connection.

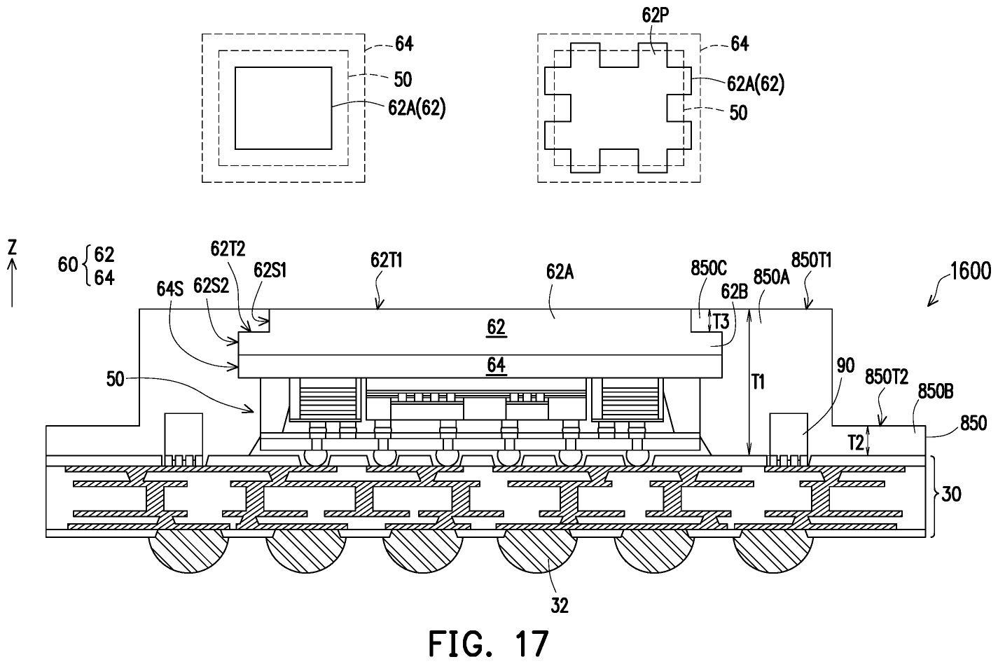

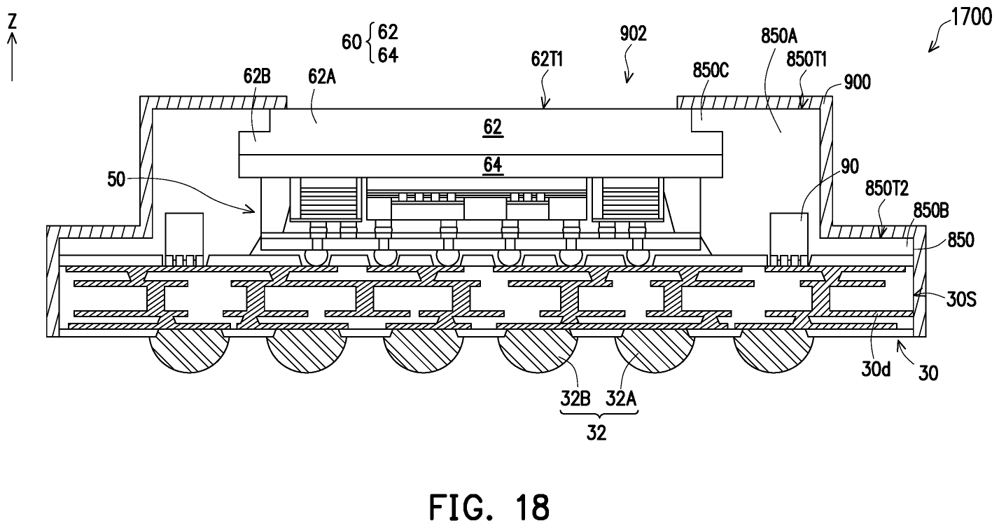

FIG. 17 and FIG. 18 illustrate cross sectional views of examples of package structures in accordance with some embodiments of the present disclosure.

Referring to FIG. 17, the package structure 1600 includes a molding layer 850 disposed over the substrate 30 and one or more packages 50 and the passive components 90 bonded to the substrate 30. In some embodiments, the package structure 1600 further includes a heat dissipating module 60 disposed on the package 50, the heat dissipating module 60 includes a metal lid 62 and a TIM 64 disposed between the metal lid 62 and the package 50. In some embodiments, the metal lid 62 is partially recessed so that the metal lid 62 has a cap portion 62A and a brink portion 62B connected to the cap portion 62A. As seen in FIG. 17, the metal lid 62 has recessed sidewalls 62S1 of the cap portion 62A, the top surface 62T1 connecting the recessed sidewalls 62S1, sidewalls 62S2 of the brink portion 62B, and the peripheral top surface 62T2 connecting the sidewalls 62S1 and 62S2. In some embodiments, the sidewalls 62S2 of the brink portion 62B are aligned with the sidewalls 64S of the TIM 64.

From the left schematic top view shown in FIG. 17, it is seen that the span of the TIM 64 of the heat dissipating module 60 is larger than the span of the package 50, and the span of the metal lid 62 is smaller than and fully overlaps with (i.e. falls within) the span of the package 50. From the right schematic top view shown in FIG. 17, it is seen that the span of the metal lid 62 is smaller than and falls within the span of the TIM 64, while the span of the metal lid 62 partially falls within the span of the package 50 and partially extends beyond (outside) the span of the package 50. From the right schematic top view shown in FIG. 17, the metal lid 62 include protruded tooth portions 62P, and the extended portions 850C of the molding layer 850 are complementary with the protruded tooth portions 62P (filling up the gaps between the tooth portions 62P).

In FIG. 17, in some embodiments, the molding layer 850 includes the innermost extended portion 850C having a thickness T3 located above the metal lid 62 (above the surface 62T2), a middle portion 850A having a thickness T1 surrounding the extended portion 850C, the heat dissipating module 60 and the package 50 and a thinner outer portion 850B having a thickness T2 surrounding the middle portion 850A. In some embodiments, the thickness T3 or T2 is smaller than the thickness T1. In some embodiment, the ratio of T3 to T1 (T3/T1) is about 0.1 to 0.7 and the ratio of T2 to T1 (T2/T1) is about 0.3 to about 0.8. As seen in FIG. 17, in some embodiments, the top surface 850T1 of the extended portion 850C and the middle portion 850A is coplanar with and flush with the top surface 62T1. In some embodiments, the extended portion 850C extends into the span of the heat dissipating module 60 and contacts the sidewalls 62S1 of the metal lid 62. Through the arrangement of the extended portion 850C and the partially recessed metal lid 62, the warpage of the package structure 1600 can be counterbalanced and the good heat dissipation efficacy can be maintained.

Referring to FIG. 18, in some embodiments, the package structure 1700, similar to the package structure 1600, further includes a shielding layer 900 covering the molding layer 850 and sidewalls 30S of the substrate 30. In some embodiments, the shielding layer 900 conformally covers the portions 850C, 850A and 850B and contacts the top surfaces 850T1 and 850T2. As seen in FIG. 18, the shielding layer 900 has an opening 902 exposing the heat dissipating module 60 (the top surface 62T1 of the cap portion 62A). In some embodiments, the shielding layer 900 functions as the electromagnetic interference (EMI) shielding layer, and the shielding layer 900 together with the metal lid 62 form an EMI shield structure to protect and shield the enclosed dies or packages from electromagnetic interference radiation or signals. In some embodiments, the EMI shielding layer 900 is electrically connected with the ground plate 30d of the substrate 30 and further electrically connected to the grounding ball 32A for grounding. In some embodiments, through the substrate 30, the package element 50 is electrically connected with other conductive balls 32B for further electrical connection.

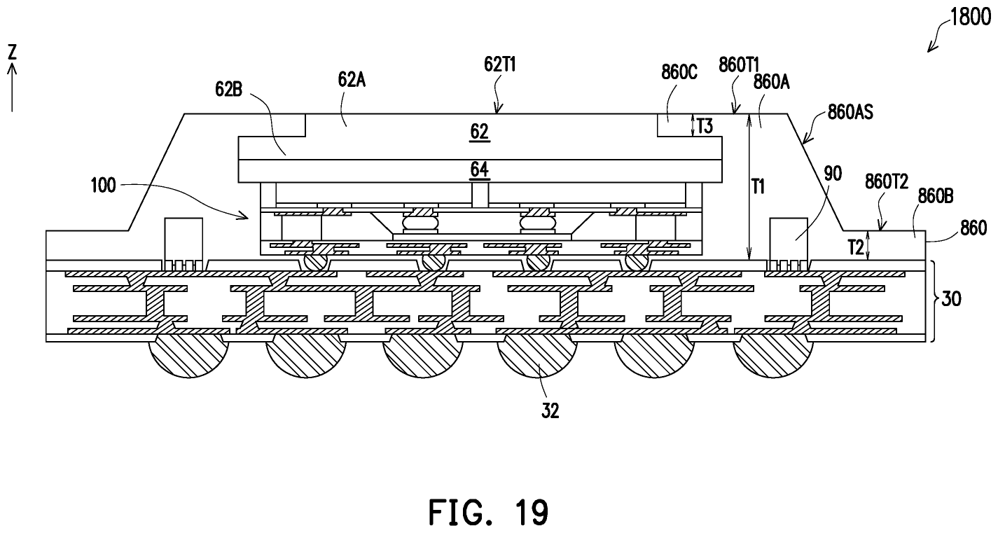

FIG. 19 illustrates a cross sectional view of an example of a package structure in accordance with some embodiments of the present disclosure.

Referring to FIG. 19, in some embodiments, the package structure 1800 includes a molding layer 860 disposed over the substrate 30, one or more semiconductor element 100 and the passive components 90 bonded to the substrate 30 and a heat dissipating module 60 disposed on the semiconductor element 100. In some embodiments, similar to the semiconductor element 100 described in the previous embodiments, the semiconductor element 100 includes or is a package including a multi-chip stacked package, a chip on wafer (CoW) package, an integrated fan-out (InFO) package, or a three-dimensional integrated circuit (3DIC) package. In some embodiments, similar to the heat dissipating module 60 described in FIG. 17, the heat dissipating module 60 includes a metal lid 62 having a cap portion 62A and a brink portion 62B connected to the cap portion 62A, and a TIM 64 disposed between the metal lid 62 and the semiconductor element 100. In some embodiments, the metal lid 62 is partially recessed so that the molding layer 860 covering the metal lid 62 includes the extended portion 860C. the molding layer 860 includes the innermost extended portion 860C having a thickness T3 located above the brink portion 62B of the metal lid 62, a middle portion 860A having a maximum thickness T1 and surrounding the extended portion 850C, the heat dissipating module 60 and the semiconductor element 100, and a thinner outer portion 860B having a thickness T2 surrounding the middle portion 860A. In some embodiments, the thickness T3 or T2 is smaller than the thickness T1. In some embodiment, the ratio of T3 to T1 (T3/T1) is about 0.1 to 0.7 and the ratio of T2 to T1 (T2/T1) is about 0.3 to about 0.8.

As seen in FIG. 19, unlike the molding layer 850 of FIG. 17, the middle portion 860A has slant sidewalls 860AS connecting the top surfaces 860T1 and 860T2. In some embodiments, the top surface 860T1 of the portions 860C and 860A is coplanar and flushes with the top surface 62T1 of the cap portion 62A of the heat dissipating module 60.

In accordance with some embodiments of the disclosure, a package structure includes a circuit substrate, a package element and a molding layer. The package element is disposed on the circuit substrate and is electrically connected with the circuit substrate. The molding layer is disposed over the circuit substrate and covers at least a top surface of the circuit substrate. The molding layer includes a first portion wrapping around sidewalls of the package element and having a first thickness, and a second portion surrounding the first portion and connected with the first portion. The first thickness of the first portion is larger than a second thickness of the second portion. A top surface of the first portion of the molding layer is higher than a top surface of the package element.

In accordance with some embodiments of the disclosure, a package structure includes a circuit substrate, a package, at least one passive component and a molding layer. The package is disposed on the circuit substrate and is electrically connected with the circuit substrate. The package includes a first semiconductor die and a second semiconductor die. The passive component is disposed on the circuit substrate and is electrically connected with the circuit substrate. The molding layer is disposed over the circuit substrate and covers the package, the passive component and at least a top surface of the circuit substrate. The molding layer includes a first portion wrapping around sidewalls of the package and having a first thickness and a second portion surrounding the first portion and connected with the first portion. The first thickness of the first portion is larger than a second thickness of the second portion. The package has a fourth thickness smaller than the first thickness of the first portion of the molding layer.

In accordance with some embodiments of the disclosure, a method for forming a package structure is provided. After providing a circuit substrate, a package element is mounted onto the circuit substrate and bonded to the circuit substrate. A molding layer is formed over the circuit substrate covering the package element. The molding layer is formed with a first portion wrapping around sidewalls of the package element and a second portion surrounding the first portion and connected with the first portion, and the first portion has a first thickness larger than a second thickness of the second portion. A top surface of the package element is not higher than a top surface of the first portion of the molding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate;
a package element, disposed on and electrically connected with the circuit substrate; and
a molding layer, disposed over the circuit substrate and covering at least a top surface of the circuit substrate,
wherein the molding layer includes a first portion wrapping around sidewalls of the package element and having a first thickness and a second portion surrounding the first portion and connected with the first portion, the first thickness of the first portion is larger than a second thickness of the second portion, and a top surface of the first portion of the molding layer is higher than a top surface of the package element.

2. The structure according to claim 1, wherein the molding layer includes a third portion disposed on the package element and connected with the first portion, the third portion has a third thickness smaller than the first thickness.

3. The structure according to claim 2, wherein a top surface of the third portion is lower than the top surface of the first portion.

4. The structure according to claim 2, wherein a top surface of the third portion is coplanar and flushes with the top surface of the first portion.

5. The structure according to claim 2, wherein a top surface of the third portion is higher than a top surface of the second portion.

6. The structure according to claim 1, wherein a top surface of the second portion is lower than the top surface of the package element.

7. The structure according to claim 1, wherein the package element includes a first semiconductor die and a second semiconductor die, the first and second semiconductor dies perform different functions.

8. The structure according to claim 7, wherein the molding layer has an opening exposing the first semiconductor die of the package element.

9. The structure according to claim 7, wherein the molding layer has an opening exposing the first semiconductor die and the second semiconductor die of the package element.

10. The structure according to claim 1, further comprising a thermal dissipating module disposed on the package element and exposed from the molding layer.

11. A package structure, comprising:
a circuit substrate;
a package, disposed on and electrically connected with the circuit substrate, wherein the package includes a first semiconductor die and a second semiconductor die;
at least one passive component, disposed on and electrically connected with the circuit substrate; and
a molding layer, disposed over the circuit substrate and covering the package, the passive component and at least a top surface of the circuit substrate,
wherein the molding layer includes a first portion wrapping around sidewalls of the package and having a first thickness and a second portion surrounding the first portion and connected with the first portion, the first thickness of the first portion is larger than a second thickness of the second portion, and the package has a fourth thickness smaller than the first thickness of the first portion of the molding layer but larger than the second thickness.

12. The package structure according to claim 11, further comprising a thermal dissipating module disposed on the package and exposed from the molding layer.

13. The structure according to claim 12, wherein the molding layer includes a third portion disposed on the thermal dissipating module and connected with the first portion, the third portion has a third thickness smaller than the first thickness.

14. The structure according to claim 13, wherein a top surface of the first and third portions is coplanar and flushes with a top surface of the heat dissipating module.

15. The package structure according to claim 12, further comprising a shielding layer covering the molding layer and sidewalls of the circuit substrate and the heat dissipating module.

16. The package structure according to claim 15, wherein the shielding layer has an opening, exposing the heat dissipating module.

17. The structure according to claim 12, wherein a top surface of the first portion is coplanar and flushes with a top surface of the heat dissipating module, and a top surface of the second portion is lower than the top surface of the package.

18. A method for forming a package structure, comprising:
providing a circuit substrate;
mounting and bonding a package element onto the circuit substrate; and
forming a molding layer over the circuit substrate covering the package element, wherein the molding layer is formed with a first portion wrapping around sidewalls of the package element and a second portion surrounding the first portion and connected with the first portion, the first portion has a first thickness larger than a second thickness of the second portion, and a top surface of the package element is not higher than a top surface of the first portion of the molding layer.

19. The method according to claim 18, further comprising disposing a thermal dissipating module on the package element before forming the molding layer.

20. The method according to claim 18, further comprising forming a shielding layer on the molding layer covering the molding layer and the circuit substrate.
